(19) United States
(12) Patent Application Publication
(10) Pub. No.: US 2011/0014400 A1
(43) Pub. Date: Jan. 20, 2011

(54) METHOD AND SYSTEM FOR MAKING THIN METAL FILMS

(75) Inventors: Jing-Yi Huang, Kaohsiung (TW); Laurence P. Sadwick, Salt Lake City, UT (US)

Correspondence Address: Guy K. Clinger, 10940 S. Parker Rd. #771, Parker, CO, 80134, US

(73) Assignee: InnoSys, Inc.

(21) Appl. No.: 12/651,959

(22) Filed: Jan. 4, 2010

Related U.S. Application Data
(63) Continuation of application No. 12/154,885, filed on May 28, 2008, now abandoned.
Application No. 12/154,885 is a continuation of application No. 11/101,877, filed on Apr. 7, 2005, now abandoned.
(60) Provisional application No. 60/560,516, filed on Apr. 7, 2004.

(51) Int. Cl. C23C 16/44; B05D 1/36; C23C 14/14; B05D 3/00; C23C 14/34

(52) U.S. Cl. 427/597; 427/404; 427/250; 427/398.1; 427/294; 204/192.1

(57) ABSTRACT

A method of forming a structure useful in all forms of deposited metals, elemental metals, metal alloys, metal compounds, metal systems, including refractory metals such as tungsten and tantalum is provided. The structure generally comprises a substrate, a first layer formed atop the substrate, and a second layer formed atop the first layer. The first layer comprises a metal, which can be chromium, gold, platinum, aluminum, nickel, or copper. The second layer comprises a metal, elemental metal, metal alloy, metal compound, or metal system comprising a refractory metal such as tungsten or tantalum. The substrate can be a silicon, quartz or glass, metal, metal oxide or nitride.

### CROSS-REFERENCE TO RELATED APPLICATIONS

This is a continuation application of U.S. patent application Ser. No. 12/154,885, filed May 28, 2008, pending, which is a continuation application of U.S. patent application Ser. No. 11/101,877, filed Apr. 7, 2005, which claims benefit under 35 U.S.C. 119(e) to application Ser. No. 60/560,516, filed Apr. 7, 2004, the disclosures of all of which are incorporated herein by reference for all purposes.

### BACKGROUND OF THE INVENTION

1. Field of the Invention

This invention relates generally to metal thin films, and in particular to metal thin films comprising refractory metals useful in fields including but not limited to semiconductor devices and fabrication, decorative metallic coatings, micro electric mechanic systems (MEMS), nanotechnology, and corrosion resistive/protective layers.

2. Description of Related Art

Refractory metals such as tungsten (W) and tantalum (Ta) are widely used in industry and research. In traditional industry applications, W is commonly used as a coating layer or a filament due to its properties such as high mechanical strength, chemical inertness, good emission current, and high melting temperature. It is also used as a sealer for vacuum packaging because of its close thermal property with certain types of glass. W metallization processes are widely used for gate contact, Ohmic contact, interconnection, and diffusion barriers in very-large-scale-integration (VLSI) circuits due to the properties of W such as low resistivity, high mechanical strength, good metal barrier performance, fine patternability, and high melting point to withstand high temperature postmetallization. It is also a good absorber for use as an X-ray mask in microelectronics photolithography. A new technique was developed using the superconducting property of W in Quasiparticle Trap-Assisted Electrothermal-Feedback Transition edge sensors (QETs). There has been increasing interest in micromachining processes, with W films being commonly used as filaments in micro-lamp devices or other areas that W is used in traditional industries (due to its strong mechanical properties). In addition to the applications mentioned above, W and other refractory metals such as molybdenum and Ta have been studied as electrode materials for thin film transistor liquid crystal displays (TFT-LCD) and emitter tip materials for flat-panel-displays (field-emission displays). Thin films of Ta are used in X-ray optics due to the high X-ray reflectivity of Al/Ta mutilayers. Ta thin films could serve as a diffusion barrier for copper (Cu) to prevent Cu being diffused into the Si substrate or into the SiO₂ dielectric layer, in addition to promoting the adhesion between Cu and the dielectric layer.

The most common deposition method for refractory metal thin films is sputtering, including direct current (DC) diode, radio-frequency (RF) diode, DC magnetron, and RF magnetron. Stresses and electrical and mechanical properties of refractory metal films deposited by sputtering deposition methods strongly depend on the film microstructure, phase composition, impurities, deposition conditions, and, most importantly, the crystal structure of the film. A good understanding of the refractory metal films is necessary to be able to optimize the performance of the refractory metal films. Many research groups have focused on refractory metal thin films. The metastable phase of some refractory metals is commonly observed in vacuum evaporation of fine particles under Ar gas. The metastable phase is also found in the refractory metal thin films such as chromium (Cr), W, and Ta deposited by the physical vacuum deposition (PVD) method. Intensive research has been conducted on Cr PVD thin films. Recently, a significant amount of research has been focused on sputter-deposited W thin films and sputter-deposited Ta thin films. This focus is due to the increased possibility of using both refractory metals in VLSI, MEMS, QET sensors, flat-panel-displays, and high temperature applications.

There are two common crystal structures in W thin films: (1) the metastable phase (β phase, A-15), and (2) the stable phase (α phase, b.c.c.).

A metastable phase has higher thermal potential energy than a stable phase. FIG. 1 shows a conceptual thermal energy diagram of the metastable and the stable phases. The metastable phase can be further irreversibly transformed to the stable phase if sufficient energy is supplied to overcome the potential barrier. This type of transformation does not require long-range diffusion. The reported temperature at which β phase W transforms to α phase W varies widely from a temperature range of 900-1000 K to over 1000 K. The transformation temperature is strongly influenced by the impurities and microstructure of the W films.

Alpha (α) phase W (the stable phase) has a body center cubic (b.c.c.) structure with a lattice constant of 3.1648 Å. The α phase is W's close-pack crystal structure with a superconducting transition temperature (T_{c}) of 0.011 K for bulk W. The β phase W is a A₃B compound, where A and B are all W atoms, with an A-15 crystal structure. The lattice constant is reported to be 5.083 Å, 5.037 Å, or 5.048±3 Å. The cubic unit cell of the A-15 structure shown in FIG. 2 is composed of four atomic layers parallel to (100) planes with two B atoms in the b.c.c. positions and six A atoms on the (001) basal planes. The β phase W films deposited by sputtering indicate that, other than ordered A-15 structures, faulted structures such as (c), (d), and (e) possibly exist in the films. Although the stable structure of W is the b.c.c. structure (α phase), the second form, the metastable structure of W (β-W with the A-15 structure), has long been recognized. The superconducting transition temperature (T_{c}) for β-W varies from 1 K to 4 K, much higher than that for α-W. β phase W is often observed in DC or RF magnetron sputter W films. It has been found that impurities, such as oxygen and nitrogen, play a significant role in stabilizing the A-15 β-W structure without forming a W oxide compound. From the X-ray photoelectron spectroscopy (XPS) results of β phase W films by several research groups, it is indicated that A-15 β-W has more oxygen incorporated in the film compared to b.c.c. α-W but not enough oxygen to exceed 25 at. %, which should be necessary if W₃O is formed.

Other than oxygen stabilized A-15 β-W, some research efforts have shown results of a stress-induced phase transformation in W thin films. Microstructure and stress of sputter-deposited W films, are highly dependent on the deposition conditions such as Ar pressure, bias voltage, presputtering time, target impurities, and substrate temperature. The research results indicate that A-15 β-W films are associated with a tensile stress and have a more porous microstructure. In contrast, b.c.c. α-W films have a more compressive stress and denser microstructure. It is not known whether the deposition conditions promote the compressive stress causing the W film to transform from the β to α phase, and therefore, a compressive stress is always required to form the b.c.c. α-W or a compressive stress is a natural consequence of the sputter-deposited b.c.c. α-W films due to its dense microstructure.

The X-ray diffraction pattern is generated using Bragg's Law (pp. 139-142 of Ref. 30). The intensity of the powder pattern lines for the diffractometer is described by

$$I = {\vert F \vert}^{2} p ( \frac{1 + {cos}^{2} 2 θ}{{sin}^{2} θ cos θ} ) {e}^{- 2 M} \qquad ( 1 )$$

where I is the relative integrated intensity, F is the structure factor described by Eq. (2), p is the multiplicity factor, M is a temperature factor described by Eq. (3), and θ is the Bragg angle.

$$\begin{matrix}{F}_{hkl} = {{\sum }_{1}}^{N} {f}_{n} {e}^{2 π i ( {hu}_{n} + {kv}_{n} + {lw}_{n} )} \\ and & ( 2 ) \\ M = \frac{6 {h}^{2} T}{mk {Θ}^{2}} [ φ ( x ) + \frac{x}{4} ] ( \frac{sin θ}{λ} ) & ( 3 ) \\ where \frac{6 {h}^{2} T}{mk {Θ}^{2}} [ φ ( x ) + \frac{x}{4} ] & \end{matrix}$$

is a constant at a fixed temperature,
λ is the wavelength of X-ray,
h, k, and l are Miller indices of the plane,
u, v, and w are the coordinates of the atom in the unit cell through the origin,
h is Planck's constant,
T is the absolute temperature in degrees Kelvin,
m is the mass of the vibrating atom,
k is the Boltzmann's constant,
Θ is the Debye characteristic temperature of the substance in K,

$$x = Θ / T , \\ and$$

$$φ ( x ) = \frac{1}{x} {\int }_{0}^{x} \frac{ξ}{ξ - 1} d ξ .$$

The b.c.c. W structure has one atom at the corner (0, 0, 0) and the other atom at the center of a cube (½, ½, ½). The Miller indices of planes, which satisfy Bragg's Law, result in a peak on the XRD pattern. The relative intensity of each of the reflection planes, calculated according to Eq. (1) for powder b.c.c. W, is shown in Table 1. It should be noted that the XRD measurement does not provide any information regarding the forbidden reflection planes. Therefore, relative quantities of grains, of which Miller indices satisfy Bragg's Law and of which are forbidden reflection planes, should not and will not be obtained by X-ray diffraction measurements.

TABLE 1
Calculated relative intensities of the diffraction lines for α-W

| hkl indices | 2θ | Relative intensity |
|---|---|---|
| 110 | 40.262 | 100 |
| 200 | 58.272 | 15.25 |
| 211 | 73.190 | 28.03 |
| 220 | 87.017 | 8.35 |

The A-15 W structure has eight atoms in a unit cell. The atoms are located at (0, 0, 0), (½, ½, ½), (¼, ½, 0), (¾, ½, 0), (½, 0, ¼), (½, 0, ¾), (0, ¼, ½), and (0, ¾, ½). The space group of the A-15 structure is Pm3n. The absent reflection planes include (100), (110), (111), (220), (300), (311), and so forth. The relative intensity of the reflection planes calculated according to Eq. (1) with a=5.0428 Å, is shown in Table 2.

In addition to the peaks shown in the diffraction lines of the ordered A-15 structure (shown in Table 2), some planes are normally absent in the diffraction pattern, which may be present only in those possible faulted structures suggested and shown in FIGS. 2 (c), (d), and (e). Table 3 shows a summary of the present and the absent planes in all possible β-W structures.

TABLE 2
Calculated relative intensities of the diffraction lines for β-W

| hkl indices | 2θ | Relative intensity |
|---|---|---|
| 200 | 35.575 | 34.80 |
| 210 | 39.942 | 100 |
| 211 | 43.942 | 74.92 |
| 222 | 63.891 | 7.26 |
| 320 | 66.833 | 18.68 |
| 321 | 69.711 | 32.34 |
| 400 | 75.319 | 12.33 |

TABLE 3
Summary of the intensity of the reflection planes, which were calculated
by Eq. (1), for all possible β-W structures shown in FIG. 2

| hkl | | Ordered | Faulted | Faulted | Faulted |
|---|---|---|---|---|---|
| indices | 2θ | structure (a) | structure (c) | structure (d) | structure (e) |
| 001 | 17.57 | — | W | S | — |
| 110 | 24.95 | — | W | — | — |
| 200 | 35.58 | W | W | W | S |
| 210 | 39.94 | S | S | W | S |
| 211 | 43.94 | S | S | S | W |
| 220 | 51.19 | — | — | — | W |
| 300 | 54.55 | — | VW | W | — |
| 221 | 54.55 | — | VW | W | W |
| 310 | 57.77 | — | VW | — | — |
| 222 | 63.89 | VW | VW | VW | VW |
| 320 | 66.83 | W | W | VW | W |
| 321 | 69.71 | W | S | W | W |
| 400 | 75.32 | W | W | VW | W |

^{a}absent
^{b}2θ calculated using a = 5.0428 Å
S = strong peak
W = weak peak
VW = very weak peak

β-W is commonly observed in DC and RF magnetron sputtered W films under normal sputtering conditions. In J. Electron. Mater. 24, 961 (1995), O'keefe et al. disclose that α phase W thin films are observed when sputtering conditions such as a 10⁻⁷ Torr base pressure and a 60- to 120-minute presputtering time (to eliminate oxygen impurities in the vacuum chamber) are used. α-W thin films sputtered under the conditions described by O'keefe et al. had lower oxygen concentration (less than −5 at. %). On the other hand, β-W thin films sputtered under normal conditions had oxygen concentrations ranging from 6 to 10 at. %. In addition to the oxygen concentration, the microstructure of β-W film has a smaller grain size (5-25 nm), higher resistivity (150-900 μΩ-cm), and a tensile stress (or negligible stress dependent on the sputtering pressure). The experimental results of O'keefe et al. support the theory that oxygen impurities stabilize A-15 β-W.

In J. Mater. Science, 36, 93 (2001), Shen et al. disclose that α-W films are deposited onto Si substrates in a mixture of Ar and O₂ (gas pressure ranging from 5 to 25 mTorr) by DC planar magnetron sputtering using a high purity (99.99%) W target. The base pressure in the sputtering chamber is 1.5×10⁻⁶ Torr. The sputtered films change from the α phase to the β phase as the partial pressure of O₂ gas in the mixture of Ar and O₂ increase. The oxygen concentration of the W film is around 12 at. % for the A-15 β-W films and 2 at. % for the b.c.c. α-W films. The A-15 β-W film has a tensile stress and a smaller grain size (5-10 nm). It is also found that the deposited W irreversibly transformed from an A-15 structure to a stable b.c.c. structure when the film thickness in the range of 100-120 nm is reached for the Ar pressure in the range of 5-12 mTorr. It is noted that no phase change is observed in A-15 β-W films up to 250 nm in thickness. The reason that W irreversibly transforms from an A-15 structure to a stable b.c.c. structure may be the oxygen absorption during longer sputtering times (i.e., thicker films that eventually receive less oxygen impurities in the chamber, which prevents the growth of the A-15 structure and promotes the growth of the b.c.c. structure).

β-W has high resistivity (100-300 μΩ-cm), a porous morphology, small grain size (0.5-40 nm), and a negligible to tensile stress for the thin film. With increasing sputtering power, substrate temperature, or film thickness, the α-W phase becomes the dominant phase in the films. In contrast, α-W is shown to have low resistivity (30-40 μΩ-cm), a dense columnar microstructure, large grain size (150-200 nm), and a strong compressive stress in the thin film state.

In sum, the β-W phase is usually found under normal routine sputtering conditions, while the α-W phase is found under sputtering conditions such as low base pressure, high purity W target, long presputtering time, low impurities in Ar gas, high sputtering power, or high substrate temperature. Generally, b.c.c. α-W is the more desired phase in W thin film. Therefore, to obtain α-W thin films without the requirement list above will be more desired and economical. β-W films have characteristics of high oxygen concentration, small grain size, tensile stress, porous morphology, and high resistivity. α-W films show characteristics such as low oxygen concentration, large grain size, compressive stress, dense columnar microstructure, and low resistivity. As the deposited thickness increases or after annealing, the A-15 β-W changes irreversibly to the b.c.c. α-W.

Sputtered metal films normally exhibit a polycrystalline structure. Normally, the deposition rate is high (300 Å/min) compared to other deposition methods such as PECVD (50 Å/min) or epitaxial growth methods (a few angstroms per minute). Due to the high deposition rate, the growth mechanism of sputtering is quite different from PECVD and epitaxial growth. Atoms that arrive at the surface of the substrate normally have limited atomic mobility. With limited long-range atomic rearrangement, sputtered metal films generally have a polycrystalline or an amorphous structure with small grain size, and have no epitaxial relationship to the substrate in general.

Sputtered metal films normally show grains with a high degree of preferred orientation. This preferred orientation depends on the crystal structures of the material and on the substrate temperature during deposition. In a b.c.c. system at room temperature, nuclei with the (110) plane parallel to the substrate surface have the lowest energy during the initial nuclei growth. This surface potential energy depends on the number of bonds per unit cell in the plane. Surfaces of the plane with a higher number of bonds per unit cell indicate less dangling bonds on the surface leading to a lower surface energy. Therefore, grains with the (110) plane usually dominate in sputter-deposited metal films with a b.c.c. crystal structure. The comparison of bonds for different plane surfaces in a b.c.c. system is shown in FIG. 3. The degree of preferred orientation will reduce as the sputter power or substrate temperature increases due to the higher atomic energy associated with the higher sputter power, the higher substrate temperature, or both.

On the other hand, the lowest state of 2-D nuclei in a face-center-cubic (f.c.c.) system is nuclei with a (111) plane parallel to the substrate surface. Therefore, sputter-deposited metal films with a f.c.c. crystal structure have a preferred orientation on the (111) plane. The bonding on different planes for a f.c.c. crystal structure is shown in FIG. 4.

In addition to the b.c.c. and the f.c.c. structures, a bonding diagram (FIG. 5) of the A-15 structure on different planes has been created to determine the possible referred orientation in the A-15 structure in sputter-deposited thin films. It can be seen from FIG. 5 that the (100) plane or the (200) plane has the highest bonding density compared with the (110), (111), and (210) planes. This finding suggests, in theory, that films with the A-15 structure would have a strong preferred orientation toward the (100) or (200) planes. Therefore, rather than having the (210) plane as the strongest peak in the powder system (see Table 2), the thin films may have the (200) plane (preferred orientation) as the strongest peak, and, if not, this peak would be very comparable to the (210) plane, in the XRD pattern.

In DC magnetron sputtering deposition systems, the stress of deposited refractory metal films strongly depends on the deposition conditions such as Ar pressure, DC bias, and substrate temperature. In the lower Ar pressure region, the film has compressive stress with low amounts of Ar incorporated into the film due to the lack of Ar ion impact and columnar microstructures. As the Ar gas pressure increases, the film goes from compressive stress very rapidly to tensile stress, which may be due to more Ar ion impact and more Ar being incorporated in the film. As the Ar pressure is further increased, the high tensile stress will pull apart atoms, which leads to an increase of the potential energy. A series of dislocations in the film will lower this potential energy. Therefore, the stress of the film decreases. Film deposited beyond this point will have a microstructure with many voids and high resistivity. This type of poor quality film is unusable in most of the thin film applications. FIG. 6 is a general plot of the deposited film stress versus Ar pressure for sputter-deposited films. The transition point, for a specific example sputtering system, from compressive to tensile stress in a W system (see FIG. 6) is around 3.5 mTorr at 2 W/cm² deposited power density and around 9 mTorr at 0.7 W/cm² deposited power density. Of course, there exists a nearly infinite family of curves that can be constructed based on sputtering parameters, including sample-to-target distance, base pressure, sputtering pressure, and other parameters (those related to the geometry of the sputtering system) and the figures shown here are to be considered as examples of such family of curves and in no way limiting of the teachings or claims made in the present invention. The Ar pressure used in the current experiment is around 4.5 mTorr, which falls in region II.

W deposited by a DC or RF magnetron sputtering system results in A-15, b.c.c., or a mix of crystal structures according to the deposition conditions. In most cases, the A-15 β-W phase is always the preferred phase under normal conditions, even though the α phase W has a lower potential energy. At least one of the following conditions has to be met in order to obtain α-W: (1) a long presputter time, (2) a low base pressure, or (3) a high substrate temperature.

Ta is a group V refractory metal and shares several similar characteristics with W. Ta is likely to have a metastable phase like W. To date, several research groups have reported a different crystal structure in addition to the b.c.c. structure for Ta thin films. It has been shown that a second type of Ta crystal structure (β-tetragonal phase) exists in Ta films which is characterized as per the Read and Altman structure or the Mills structure.

The b.c.c. phase Ta is a stable phase of Ta. The β-tetragonal phase is a metastable phase of Ta. It is not clear whether there is an A-15 metastable phase of Ta in addition to the β-tetragonal Ta. The stable phase of Ta is a b.c.c. structure with a lattice constant around 3.301 Å, depending on the intrinsic stress of the film. The second phase of Ta is a β-tetragonal phase with lattice constants of a=10.194 Å and c=5.313 Å. The atomic arrangement of β-tetragonal Ta is shown in FIG. 7. The atoms at elevation of z=0 or z=c/2 form a pseudohexagonal array. Each pseudohexagon is composed of four {410} and two {330} planes. The angle between (410) and (140) is 62° and the angle between (410) and (330) is 59°. The third phase of Ta purportedly has an A-15 crystal structure with a lattice constant around 5.26 Å which is calculated based on the same A-15 structure as the W with Ta atoms. A list of the possible reflection planes in the X-ray diffraction pattern of Ta for the b.c.c. structure, A-15 structure, and β-tetragonal structure is summarized in Table 15. Table 15 shows two planes that have close 2θ values: (1) the (110) of b.c.c. Ta with the (202) of β-tetragonal Ta or the (210) of A-15 Ta, and (2) the (002) of β-tetragonal Ta and the (200) of A-15 Ta.

In sum, in the prior art, the metastable β-W or β-Ta phase is usually found under normal routine sputtering conditions, while stable α-W or α-Ta phase is found only under strict sputtering conditions such as low base pressure, high purity W target, long presputtering time, low impurities in Ar gas, high sputtering power, low oxygen background and residual pressure, or high substrate temperature. Generally, b.c.c. α-W or α-Ta is the more desired phase in W or Ta thin films. It is desirable to obtain α-W or α-Ta thin films without the above strict requirement. Accordingly, further developments in tungsten and tantalum thin films are needed.

### SUMMARY OF THE INVENTION

The present invention provides methods of forming a structure useful in a variety of technical fields including semiconductor devices and fabrication, decorative metallic coatings, micro electric mechanic systems (MEMS), nanotechnology, and corrosion resistive/protective layers. In one embodiment, the structure generally comprises a substrate, a first layer formed atop the substrate, and a second layer formed atop the first layer. The first layer comprises a metal. The metal can be transition metal such as chromium, gold, platinum, aluminum, nickel, or copper. The second layer comprises a refractory metal such as tungsten or tantalum. The substrate can be a silicon, quartz, glass, alumina, sapphire substrate, a metal, an oxide, or a compound substrate such as gallium arsenide (GaAs).

In some embodiments, the first layer comprises chromium, gold or platinum and the second layer comprises tungsten or tantalum. In a specific embodiment, the first layer is a chromium layer and the second layer is a tungsten or tantalum layer.

In other embodiments, the structure can comprise a third layer formed atop the second layer. In a specific embodiment, the first layer comprises chromium, gold or platinum, the second layer comprises tungsten, and the third layer comprises tantalum. In another specific embodiment, the first layer comprises chromium, gold or platinum, the second layer comprises tantalum, and the third layer comprises tungsten.

In one aspect, the present invention provides methods for making metal thin films. One method comprises the steps of forming a first layer of chromium, gold, platinum, aluminum, nickel, or copper on a substrate and forming a second layer of tungsten or tantalum atop the first layer. The first or second layer can be formed by sputtering. The sputtering can be conducted for 30 to 60 seconds or longer or shorter depending on the details of the sputtering systems under a base pressure in the range from about 1.0×10⁻⁷ Torr to about 5.0×10⁻⁵ Torr. In some embodiments, the sputtering can be conducted under a pressure in the range from about 3.0×10⁻⁵ Torr to about 5.0×10⁻⁵ Torr.

In a specific embodiment, the method comprises the steps of forming a first layer of chromium, gold, or platinum on a substrate, forming a second layer of tungsten atop the first layer, and forming a third layer of tantalum atop the second layer.

In another specific embodiment, the method comprises the steps of forming a first layer of chromium, gold, or platinum on a substrate, forming a second layer of tantalum atop the first layer, and forming a third layer of tungsten atop the second layer.

### BRIEF DESCRIPTION OF THE DRAWINGS

These and various other features and advantages of the present invention will become better understood upon reading of the following detailed description in conjunction with the accompanying drawings and the appended claims provided below, where:

FIG. 1 is a schematic potential energy diagram for the α and β phases of W;

FIG. 2 shows A-15 (A3B) structures: (a) is a four-layer stacking arrangement of atomic planes in the A-15 (A3B) structure; layers A, B, C, B are spaced by ¼ a; B atoms are indicated by filled circles; (b) is a three-dimensional A-15 (A3B) crystal structure; (c), (d), and (e) are possible faulted A-15 structures;

FIG. 3 is a sketch showing the bonds for different planes in a b.c.c. system;

FIG. 4 is a sketch showing the bonds for different planes in a f.c.c. system;

FIG. 5 is a sketch showing the bonds for different planes in a A-15 system;

FIG. 6 is a plot showing film stress versus Ar pressure for sputter-deposited films;

FIG. 7 is a four-layer stacking arrangement of atomic planes in the β-tetragonal Ta crystal structure;

FIG. 8 is a schematic diagram showing a sputtering system in accordance with an embodiment of the present invention;

FIG. 9 is a sketch of the relationship between the scanning distance W, displacement h, and radius R where R=W²/(8h) in accordance with an embodiment of the present invention;

FIG. 10 is a schematic illustrating a four-point probe measurement apparatus in accordance with an embodiment of the present invention;

FIG. 11 shows an X-ray diffraction pattern of W film deposited on quartz, from 2θ=30 to 65 degrees in accordance with an embodiment of the present invention;

FIG. 12 shows X-ray diffraction results from three W thin films deposited on different substrates at different positions in accordance with an embodiment of the present invention;

FIG. 13 schematically shows sample positions in a sputtering chamber in accordance with an embodiment of the present invention;

FIG. 14 shows the plasma distribution of cathode 3 under normal and typical sputter conditions;

FIG. 15 shows X-ray diffraction scans of W films deposited at different positions in accordance with an embodiment of the present invention: (a) the 2θ XRD scan from 30 to 65 degrees; (b) an expanded view at 2θ around 35.5 degrees;

FIG. 16 shows an X-ray diffraction pattern of W deposited on a Cr interlayer on a quartz substrate in accordance with an embodiment of the present invention;

FIG. 17(a) shows X-ray diffraction results of three W films deposited on a Cr interlayer on different substrates and at different positions in accordance with an embodiment of the present invention; FIG. 17(b) is an expanded view of the peak at 2θ˜40 degrees;

FIG. 18 shows XRD results of W on Cr film (Cr/W/Cr) in accordance with an embodiment of the present invention; FIG. 18(a) is Won Cr film as-deposited, and FIG. 18(b) is after annealing at 600° C. for 5 minutes;

FIG. 19 shows XRD results of pure W film, with FIG. 19(a) being pure W film as-deposited and FIG. 19(b) being after annealing at 600° C. for 5 minutes in accordance with an embodiment of the present invention;

FIG. 20 shows XRD results of films deposited at base pressures of 1.2×10⁻⁶, 1.0×10⁻⁵, and 5.0×10⁻⁵ Torr, respectively in accordance with an embodiment of the present invention; (a) with intensity plotted in a log scale, and (b) with intensity plotted in a linear scale.

FIG. 21 shows the intensity of the β-W (200) peak from the XRD scans for pure W films at different base pressures in accordance with an embodiment of the present invention;

FIG. 22 shows relative intensity of the β-W (210) peak to the β-W (200) peak from the XRD scans for pure W films at different base pressures in accordance with an embodiment of the present invention; the solid line shows the trend tendency of the data;

FIG. 23 shows resistivity of pure W films deposited at different base pressures in accordance with an embodiment of the present invention; the solid line shows the trend tendency of the data;

FIG. 24 shows the relationship between the films' microstructure and the films' electrical property (resistivity) in accordance with an embodiment of the present invention; FIG. 24(a) is β-W (200) peak intensity versus film resistivity and FIG. 24(b) is relative intensity of β-W (210) to β-W (200) versus film resistivity; the solid line is the linear best fit to the data.

FIG. 25 shows intensity of W deposited on Cr interlayer films at the base pressures of 1.2×10⁻⁶, 1.0×10⁻⁵, and 5.0×10⁻⁵ Torr, respectively in accordance with an embodiment of the present invention; FIG. 25(a) shows intensity plotted in log scale and FIG. 25(b) shows intensity plotted in linear scale;

FIG. 26 shows X-ray diffraction of W/Cr film deposited at a base pressure of 5×10⁻⁵ Torr in accordance with an embodiment of the present invention;

FIG. 27 shows the percentage of A-15 β-W in W films deposited at different base pressures in accordance with an embodiment of the present invention; the amount of A-15 β-W is measured by the relative intensity of the β-W (200) peak;

FIG. 28 shows the resistivity of W films deposited on Cr versus base pressures in accordance with an embodiment of the present invention;

FIG. 29 shows the relationship between the resistivity and the relative intensity of β-W (200) in W films deposited on Cr in accordance with an embodiment of the present invention; the solid line is the trend tendency of the data;

FIG. 30 shows the XRD result of a Ta thin film deposited on a glass substrate in accordance with an embodiment of the present invention;

FIG. 31 shows the XRD results of Ta/W films and the Ta/W/Cr films in accordance with an embodiment of the present invention; vertical lines are the position of the respective peaks;

FIG. 32 schematically shows a film structure in accordance with one embodiment of the present invention; and

FIG. 33 schematically shows a film structure in accordance with another embodiment of the present invention.

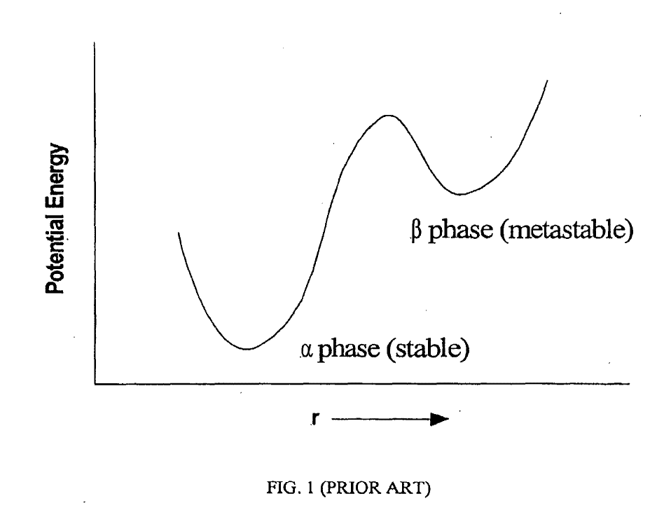

### DETAILED DESCRIPTION OF THE INVENTION

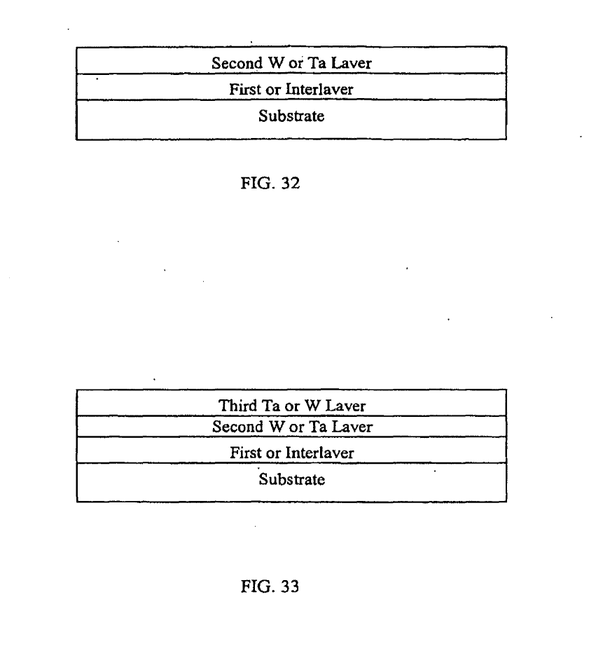

The present invention provides a method of forming a structure useful in a large variety of applications and uses, including semiconductor devices and fabrication, MEMS, micromachining and a vast number of other applications. In particular, the present invention provides a method of making thin metal films having body centered cubic and face centered cubic structures useful in industries and research. Exemplary metals include refractory metals such as tungsten (W) and tantalum (Ta). Other metals include but are not limited to molybdenum (Mo), rhodium (Ru), niobium (Nb), platinum (Pt), palladium (Pd), and cobalt (Co). In one embodiment shown in FIG. 32, the structure generally comprises a substrate, a first layer formed atop the substrate, and a second layer formed atop the first layer. The first layer comprises a metal for controlling the properties of subsequent metal layer(s), which includes but is not limited to: chromium, gold, platinum, aluminum, nickel, or copper. The second layer comprises a refractory metal and/or elemental metal, and/or metal alloy, and/or metal compound and/or metal system. Exemplary refractory metals include tungsten or tantalum or other refractory metals. The substrate can be, for example, silicon, quartz, ceramic, or glass; other substrates, including metals and metal oxides and nitrides, elemental oxides and nitrides and the like, can also be considered for use in the invention disclosed herein.

In some embodiments, the first layer comprises chromium, gold or platinum and the second layer comprises tungsten or tantalum. In a specific embodiment, the first layer is a chromium layer and the second layer is a tungsten or tantalum layer.

In other embodiments shown in FIG. 33, the structure can comprise a third layer formed atop the second layer. In a specific embodiment, the first layer comprises chromium, gold or platinum, the second layer comprises tungsten, and the third layer comprises tantalum. In another specific embodiment, the first layer comprises chromium, gold or platinum, the second layer comprises tantalum, and the third layer comprises tungsten.

In one aspect, the present invention provides methods for making metal thin films of a certain preferred crystal orientation. One method comprises the steps of forming a first layer or interlayer of chromium, gold, platinum, aluminum, nickel, or copper on a substrate and forming a second layer of tungsten or tantalum on the first layer. The first or second layer can be formed by sputtering. In one embodiment, the sputtering is conducted for 30 to 60 seconds under a pressure in the range from about 1.0×10⁻⁷ Torr to about 5.0×10⁻⁵ Torr, or alternatively in the range of from about 1.0×10⁻⁷ Torr to about 3.5×10⁻⁵ Torr. In some embodiments, sputtering is conducted under a pressure in the range from about 3.0×10⁻⁵ Torr to about 3.5×10⁻⁵ Torr. Other methods for forming the metal thin films of the present invention include, but are not limited to thermal evaporation and deposition, electron beam evaporation, other variants of physical vapor deposition (PVD), chemical vapor deposition (CVD) and atomic layer deposition (ALD).

In a specific embodiment, the method comprises the steps of forming a first layer of chromium, gold, or platinum on a substrate, and forming a second layer of tungsten atop the first layer. In another specific embodiment, the method comprises the steps of forming a first layer of chromium, gold, or platinum on a substrate, forming a second layer of tungsten atop the first layer, and forming a third layer of tantalum atop the second layer.

In still another specific embodiment, the method comprises the steps of forming a first layer of chromium, gold, or platinum on a substrate, forming a second layer of tantalum atop the first layer, and forming a third layer of tungsten atop the second layer.

In another aspect of the present invention, a device is provided comprising a substrate carrying a tungsten layer formed predominately of an alpha-phase body centered cubic (b.c.c.) structure, and a chromium interlayer formed between the structure and tungsten layer.

For the purposes of the present teaching, “predominately” is generally meant to be more than 50%, and up to 100%. However, this is merely meant to serve as a guideline.

The following systems and examples for making tungsten and tantalum thin films are provided to illustrate the present invention. It should be pointed out that these systems and examples are for illustrating purposes and not intended to limit the scope of the invention in any way.

### Sputtering System

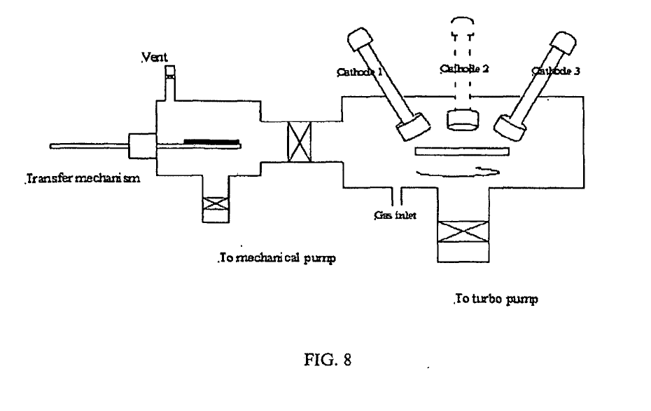

The Denton Discovery 18 Sputtering System shown in FIG. 8, available from Denton Vacuum, Moorestown, N.J., is used for depositing metal films in the present invention. It should be noted that the Denton Discovery 18 system is presented for illustrating purposes only and is not intended to limit the scope of the present invention. Other systems such as PVD, CVD, or ALD systems, and certainly other makes and models of sputtering systems and processes, can be used to deposit the metal thin films according to the method of the present invention.

The sputtering system shown in FIG. 8 has DC and RF magnetron sputter cathodes. The magnetic field configuration redirects electrons to stay near the target surface. This high flux of electrons creates a high-density plasma. The advantages of magnetron sputter systems include low deposition pressure, high deposition rate, low heat generation, and lower film contamination. The sputtering system shown includes three cathodes, each of which is in a confocal cathode arrangement and focused on a central area of the substrate stage as shown in FIG. 8. The substrate-to-target distance is around 2.75″. The substrate stage rotates during sputtering. This design allows some compensation for the high sputtering rate at the edge of the stage by the rotation pattern with respect to the target. Therefore, a fine adjustment of the target to substrate distance and the rotation speed can be made to ensure the uniformity of deposited films. This confocal cathode arrangement provides more uniform film thickness (±5% uniformity) throughout the 6″ table with a 3″ target compared to a planar cathode configuration. A load-lock chamber is connected to the main chamber with an automatic gate valve. The load-lock chamber reduces the frequency of exposing the main chamber to atmosphere. Therefore, there should be less contamination in the main chamber. There are two pressure gages in the main chamber: (1) one is a cold cathode gage for base pressure measurement and (2) the other is a thermocouple gage for the sputtering gas pressure measurement.

### Film Deposition

The DC magnetron sputter system shown in FIG. 8 was used for the sputtered films in this exemplary embodiment. Si substrates covered with thermally grown SiO₂ amorphous layers were used to prevent any epitaxial relationship between the substrate and the sputtered film due to the amorphous microstructure of thermally grown SiO₂. The thickness of the SiO₂ amorphous layer was around 5000 Å. The thickness of the SiO₂ amorphous layer was not critical in this case as long as the Si substrate was entirely covered. Other substrates such as glass sides, quartz, and Si wafers (without a SiO₂ layer) were also used and, in general, most any substrate will work with the techniques disclosed in the present invention. W films were sputtered on different substrates with or without an interlayer under normal sputter conditions such as a base pressure around the high 10⁻⁷ to low 10⁻⁶ Torr, DC sputter power of 200 W, and Ar pressure of 4.6 mTorr. All targets were presputtered for one minute under the deposition conditions while the substrate was isolated from the plasma by a shutter. This procedure removes some of the contamination and oxide layer on the target. If targets were exposed to atmosphere for a long time, a longer presputter time may be desired. The purity of the W target was of 99.95% purity, and the Ar gas used for sputtering was of 99.999% purity. The purity of other materials used in this study is listed in Table 4. A run sheet of the sputter procedure is shown in steps as follows.

1. Substrate cleaning. A standard cleaning solution (H₂O₂:H₂SO₄=1:3 in volume) was used to remove any contamination of the substrates.

2. Preparation for sputtering. After Step 1, the substrates were loaded into the load-lock chamber. Then the load-lock chamber was pumped down automatically. Once the chamber was pumped down, the substrates were transferred to the main chamber. After the main chamber was pumped down to the base pressure, the substrates are ready for sputtering.

3. Presputter targets. Presputtering the targets was desired in order to remove any contamination and any oxide layers on the surface of the target. One minute was normally sufficient, but more time may be desired if the target was exposed to atmosphere before the samples were loaded to account for more contamination and thicker oxide layers.

4. Sputtering. The sputtering power used for the W deposition was 200 Watts. If there was an interlayer, it was sputtered at 250 Watts to a thickness of around 200 Å. 250 Watts could yield 200 Å in a reasonable amount of time (around 30 seconds to 2 minutes). It should be noted that these numbers and values are merely illustrative and not limiting of the present invention.

TABLE 4
Purity of sputter target materials used in the current study

| Material | Purity (%) |
|---|---|
| Al | 99.99 |
| Au | 99.99 |
| Cr | 99.95 |
| Cu | 99.997 |
| Ti | 99.9 |
| Ta | 99.95 |

### Characterization

### X-Ray Diffractometer

After sputter deposition, X-ray diffraction measurements are performed on the samples. The crystal structures of the films are determined from the measured X-ray diffraction (XRD) patterns using a Phillips X'pert MPD Diffractometer with Cu K_{α}, radiation operated at 40 kV and 40 mA.

### Crystallography and Lattice Constant:

First, every peak in the XRD pattern was identified by a comparison of W's JCPDS data or the calculation discussed above. W films with α phase showed a strong (110) plane peak for a 2θ around 40.26 degrees. On the other hand, W films with the A-15 β phase show a strong (200) plane peak for a 2θ around 35.57 degrees. Once the plane of the peak is determined, the lattice constant can be calculated by the following formula:

α=λ\sqrt{h²+k²+l²}/(2 sin θ) (4)

### Grain Size

The average grain size in the film can also be determined from the X-ray diffraction pattern. The grain size depends on the broadening of the appropriate diffraction peak or peaks, in this case for W, the (110) plane peak of α-W or the (200) plane peak of β-W in the XRD pattern. The relative grain size is given by

$$t = \frac{0.9 λ}{B cos θ} \qquad ( 5 )$$

where
t=the diameter of the grain,
B=the broadening of the diffraction line measured at half its maximum intensity or full width at half maximum intensity (FWHM), and
λ=the X-ray wavelength.
For a more accurate result, B is the extra broadening due to the grain-size effect alone. Therefore, B is obtained by:

B²=B_{M}²−B_{S}² (6)

where B_{M}=FWHM and
B_{S}=the broadening of the diffraction line measured at half its maximum intensity from the standard sample.

The standard sample should be either a single crystal sample or a film sample with particle size (grain size)>1000 Å, which has a peak position close to the peak used to measure grain size. The XRD technique will not accurately measure films with grain size larger than 1000 Å because the broadening of the grain size beyond 1000 Å is close to the broadening of a single crystal. In this study, all grain sizes were estimated by Eq. (5) with B=B_{M}.

Stress and strain: The XRD measurement can also be used to measure the strain or the stress of the material. A more accurate value of the stress in a thin crystalline film can be obtained by measuring the separation of peaks on a series of X-ray rocking curves. In addition to this technique, an estimated stress of the film can be calculated from a standard XRD pattern. The stress of the film is given by

$$σ = - \frac{E}{1 - v} ln ( \frac{{a}_{0}}{{a}^{*}} ) \qquad ( 7 )$$

where σ is the stress of the film, E is the Young's modulus of the film, ν is the Poisson's ratio of the film, α₀ is the lattice constant obtained from the XRD pattern, and α* is the lattice parameter corresponding to the microstructural state of the film when one considers only the low energetic particles during the thin film growth (stress free). This measurement is actually an elastic strain measurement from which stress is inferred by Eq. (8). The Young's Modulus (E) of the film has to be known in order to calculate the stress from Eq. (8). The Young's Modulus (E) value of W used for Eq. (8) is 402.5 GPa.

### Surface Profiler

A surface profiler was used for high precision surface measurements in a wide range of applications, including step heights, microroughness, and thin film stresses. The surface profiler used in this project was a Veeco Dektak 3. This type of surface profiler consists of a stylus, which contacts and scans on top of the sample surface. The stylus moves up and down depending on the sample surface. The accuracy of the Veeco Dektak 3 in the vertical direction is around 50-100 Å.

Thickness: Initially, several films were deposited with different sputtering times to calculate the deposition rate. After this simple calibration method, the film thickness was estimated by this deposition rate and the sputtering duration. A more accurate method is to chemically etch the film in order to create a step so that the step height can be measured using the Veeco Dektak 3.

Stress: Stress and strain in thin films are important for microelectronic applications. The balloon measurement (i.e., Stoney method or curvature method) was chosen for convenience. This method was first introduced by Stoney in 1909 and is widely used for measuring film stress. The technique is based on measuring the curvature of a substrate produced by the stress in the film. In this case, the curvature of the substrate is measured by the Dektak 3 surface profiler. The stress in the film is given by

σ=E_{S}T²/[6(1−υₛ)tR] (8)

where
σ=film stress (GPa),
E_{S}=the Young's modulus for the substrate (GPa),
ν_{S}=the Poisson's ratio for the substrate,
T=the substrate thickness (μm),
R=the radius of curvature (μm) for the film, and
t=the film thickness (μm).

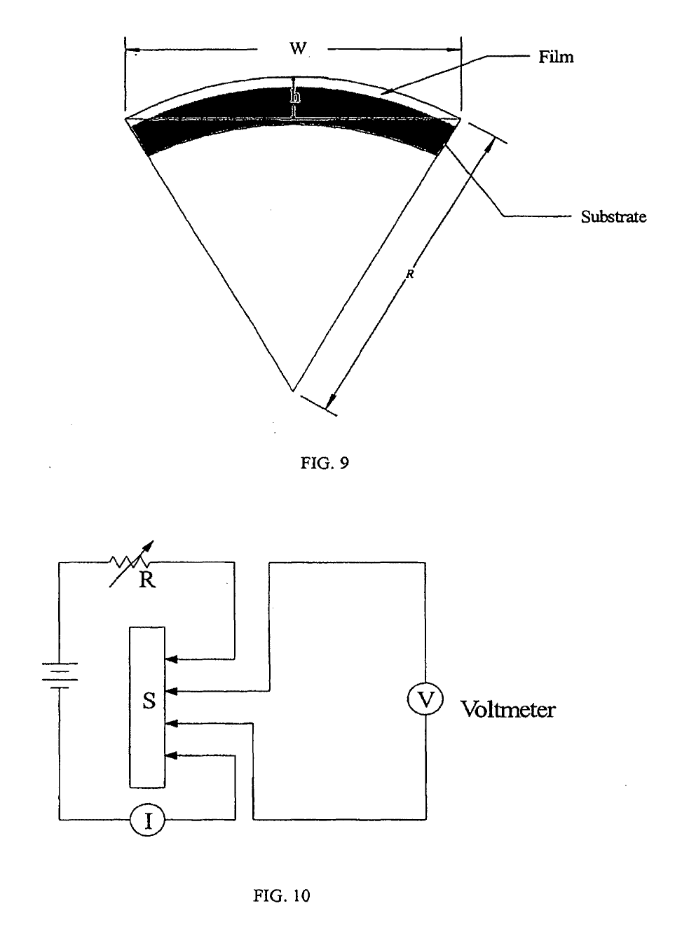

In this formula, the radius of curvature for the film can be calculated from the displacement and scanning distance data obtained from the Dektak 3 surface profiler (FIG. 9). Note that only the properties of the substrate and the thickness of the film need to be known; the elastic properties of the film are not needed to determine the stress by this method. Most of the thin films formed by sputter deposition are under biaxial stress.

The substrates used in this study were not stress free to begin with; this is true even for high-quality Si wafers. Any preexisting curvature should and can be removed mathematically. Thus, it is desirable to measure the curvature of the substrate initially and carry out a point-by-point subtraction of the measurement before and after the film is deposited. Therefore, h is the difference between the displacement measured with film and that measured without the film at the center point. Si wafers were used as the substrate for stress measurements due to the Si wafer having an almost stress-free property and a very well characterized Young's modulus and Poisson's ratio.

### Four-Point Probe Measurement

The four-point probe is the most common method of measuring sheet resistivity. Four equally spaced metal probes were used to contact the film surface. A measured current I was passed through the two outside probes, and the voltage drop V between the two inside probes was measured by a voltmeter, as shown in FIG. 10. For a finite size sample, the sheet resistance is given by

$${ρ}_{s} = C \frac{V}{I} in Ω / • \qquad ( 9 )$$

where V is the measured voltage, I is the current, and C is the correction factor as shown in Table 4A. The sheet resistance should be verified with different values of current. Any difference between the two measurements indicates contact resistance between the probes and the film or possibly a heating of the device under test condition. The resistivity of the material was determined by multiplying the sheet resistance by the thickness of the film.

Since there is significant difference in resistivity between the α phase and the β phase of W, the resistivity of the films could be roughly used as an indication of the phase in the W film. The resistivity should closely correlate to the crystallography phases determined from X-ray diffraction measurements.

TABLE 4A
Correction factor C for various sizes of rectangular
shapes in the four point probe measurement

| d/s | a/d = 1 | a/d = 2 | a/d = 3 | a/dβ4 |
|---|---|---|---|---|
| 1.0 | | | 0.9988 | 0.9994 |
| 1.25 | | | 1.2467 | 1.2248 |
| 1.5 | | 1.4788 | 1.4893 | 1.4893 |
| 1.75 | | 1.7196 | 1.7238 | 1.7238 |
| 2.0 | | 1.9454 | 1.9475 | 1.9475 |
| 2.5 | | 2.3532 | 2.3541 | 2.3541 |
| 3.0 | 2.4575 | 2.7000 | 2.7005 | 2.7005 |
| 4.0 | 3.1137 | 3.2246 | 3.2248 | 3.2248 |
| 5.0 | 3.5098 | 3.5749 | 3.5750 | 3.5750 |
| 7.5 | 4.0095 | 4.0361 | 4.0362 | 4.0362 |
| 10.0 | 4.2209 | 4.2357 | 4.2357 | 4.2357 |
| 15.0 | 4.3882 | 4.3947 | 4.3947 | 4.3947 |
| 20.0 | 4.4516 | 4.4553 | 4.4553 | 4.4553 |
| 40.0 | 4.5120 | 4.5129 | 4.5129 | 4.5129 |
| ∞ | 4.5324 | 4.5324 | 4.5324 | 4.5324 |

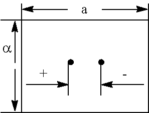

Points are centered on the sample and along the major axis

### EXAMPLES

The following examples are provided to illustrate the present invention and are not intended to limit the scope of the present invention in any way.

### Example 1

### W on SiO₂ and W on Si

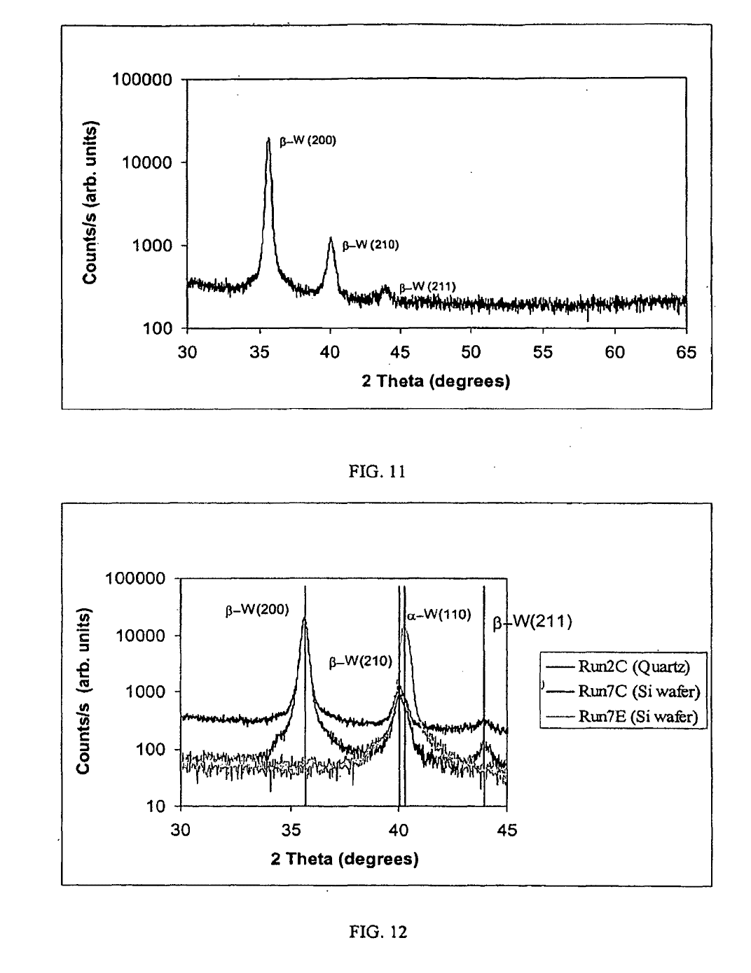

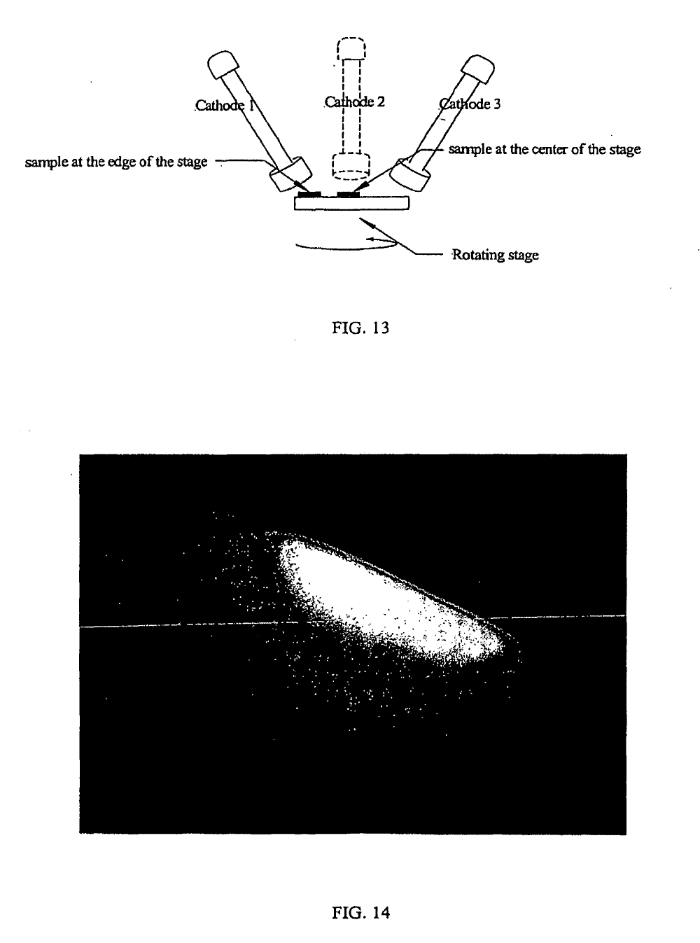

The sputter-deposited W thin films were fabricated under general deposition conditions. Films were characterized and compared with prior art films. W films were deposited by DC magnetron sputtering at a base pressure of around the high 10⁻⁷ to low 10⁻⁶ Torr range, as measured by a cold cathode gage, with an Ar pressure of around 4.5 mTorr with an Ar flow rate of 30 sccm, and a DC power of 200 W. The rate of W deposited under this condition was around 228 Å per minute. A 1-minute presputter was conducted for all deposited films. Glass, quartz, and Si wafers were used as substrates on which the W films were sputtered. Si wafers were used as the substrates for film stress measurements due to the Si wafers' almost stress-free property and well-known mechanical properties. FIG. 11 shows an X-ray diffraction pattern of a W film deposited on a quartz substrate which was scanned from 2θ=30 to 65 degrees. FIG. 12 is the X-ray diffraction results from three W thin films on different substrates at different positions (center of the stage or edge of the stage in the sputter chamber as shown in FIG. 13). Table 5 is a list of parameters obtained from the XRD results of W films deposited on quartz and a Si wafer. Table 6 summarizes the film properties obtained from the W films deposited at the center and at the edge of the stage, respectively.

TABLE 5
XRD results and electrical properties of W films
deposited on glass and silicon substrates

| | W—C | W on Si |
|---|---|---|
| Substrate | Quartz | Si |
| First strong peak positions | 35.576 | 35.598 |
| (2θ) | | |
| A-15 β-W | 100% | 100% |
| b.c.c. α-W | 0% | 0% |
| (200) Relative intensity (%) | 100 | 100 |
| (210) Relative intensity (%) | 3.4 | 1.12 |
| (211) Relative intensity (%) | 0 | 0 |
| FWHM (B_{M})(θ) | 0.2418 | 0.2679 |
| Lattice constant (Å) | 5.043 | 5.040 |
| Grain Size (Å) | 355 (±17*) | 319 (±17*) |
| Sheet resistance (Ω/□) | 8.87 | 8.11 |
| Film thickness (Å) | 1560 | 1429 |
| Resistivity (μΩ-cm) | 127 | 127 |

*The error is calculated based on the step size of 2θ = 0.02 degree in the XRD scan.

TABLE 6
Summary of film properties from film deposited
at the center and at the edge of the stage

| | Center | Edge |
|---|---|---|
| Microstructure | A-15 β-W | b.c.c. α-W |
| Sheet resistance (Ω/□)* | 8.87 | 1.13 |
| Film thickness (Å) | 1429 | 1414 |
| Resistivity (μΩ-cm) | 127 | 16 |
| Stress** (GPa) | 2.26 | 0.93 |

*Measured by Four-point probe measurement.
**Obtained by the balloon method (Stoney's method), which was discussed in Section 3.4.

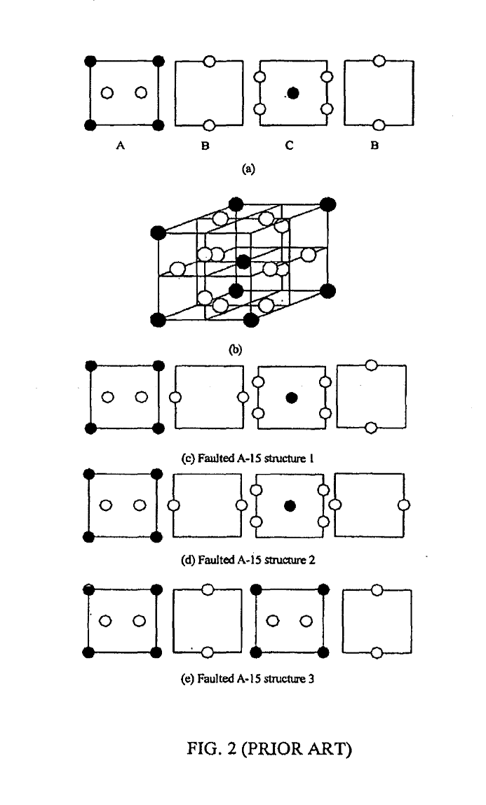

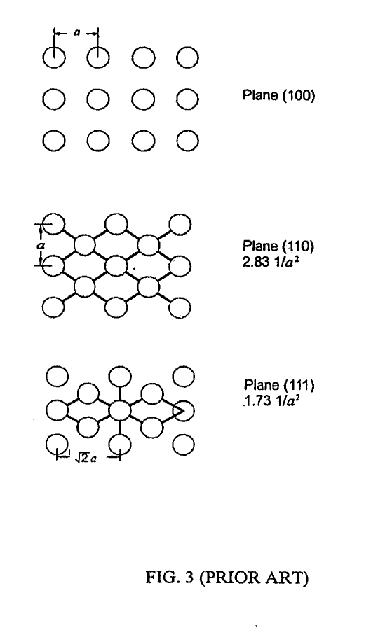

In FIG. 11, the peak shown at 2θ35.3761 degrees was identified as the (200) plane of A-15 β-W. This peak is the strongest peak shown in the XRD scan. The second strongest peak is the (210) at 2θ˜40 degrees. For the A-15 powder XRD pattern (see Table 2), the (210) peak would be the strongest peak followed by the (211) peak. The XRD pattern for the W film on a quartz substrate had the (200) peak as the strongest peak followed by the (210) peak with a relative intensity of 3.4%. This film shows a strong (200) preferred orientation, i.e., a (200) texture. In other words, most of the grains in the film have the (200) plane perpendicular to the substrate with different rotations. Comparing the results with Table 3, the faulted structure c and d were unlikely to be present in the A-15 β-W films. The ordered structure is most likely to be the dominant crystal structure with some amount of the e-type faulted structure being present (as shown in FIG. 2). The lattice constant calculated from the (200) peak in the XRD pattern is 5.043 Å (5.0356 Å from the close-pack model). The reported lattice constant in the art is between 5.02 and 5.05 Å. By measuring the full width at half maximum (FWHM) intensity, the relative grain size can be obtained from Eq. (5). For the films deposited on quartz, the grain size was 355 Å. This number is considerably larger compared to what has been reported in the prior art, which is typically in the range of 50-100 Å (as shown in Table 1).

A W sample with a thickness around 550 Å was sputtered, and XRD measurements were carried out to determine the grain size of A-15 β-W in this film. The grain size was 157 Å which is close to the number reported by other research groups (see Table 1). This finding indicates that the grain size of 355 Å for the A-15 β-W structure can be obtained without transforming into the stable b.c.c. α-W in W films with a thickness around 1500 Å. Therefore, small grain size (50 Å) or large grain size (355 Å) could be a result of the formation of the A-15 structure under different deposition conditions, which could provide thicker A-15 β-W films without transforming to b.c.c. α-W. It should be noted that β phase W was observed even with a base pressure of 8.3×10⁻⁷ Torr (measured by the cold cathode gage). The sheet resistance measured by the four-point probe method is 8.87Ω/□ for the film deposited on quartz. The resistivity calculated from the sheet resistance is 127 μΩ-cm.

From FIG. 12 and Table 5, it is clear that there was no observed difference between films deposited on the Si wafers and on the quartz substrates. However, films at the center of the stage compared with films at the edge of the stage showed a significant difference in crystal structure, stress, and resistivity (see Table 6). The sample located at the edge of the stage (see Table 6) showed a much lower sheet resistance (1.13Ω/□) and lower tensile stress than the sample located at the center of the stage. The XRD measurement result shows a phase difference between samples deposited at the center of the stage and samples deposited at the edge of the stage. It is clear that the low sheet resistance or resistivity of the film deposited at the edge was due to the α phase W, since α-W generally has a lower resistivity than β-W. It is suggested that the main cause of the low resistivity was due to a phase change. The actual mechanism causing the phase change and low stress at the edge of the sample may be explained by the focal configuration of targets in the Denton Discovery 18 Deposition System used. The focal point of the three targets was below the stage, thus generating higher plasma at the edge of the stage and lower plasma at the center of the stage (shown in FIG. 14). With stage rotation, the uniformity of the film thickness throughout the stage could reach <5%. Higher plasma concentration at the edge of the stage provides the atoms with more energy to rearrange and overcome the potential barrier to reach a lower energy state configuration (α phase). The direct result is that a film deposited under a higher concentration plasma may have less stress and possibly undergo phase change towards a more stable phase.

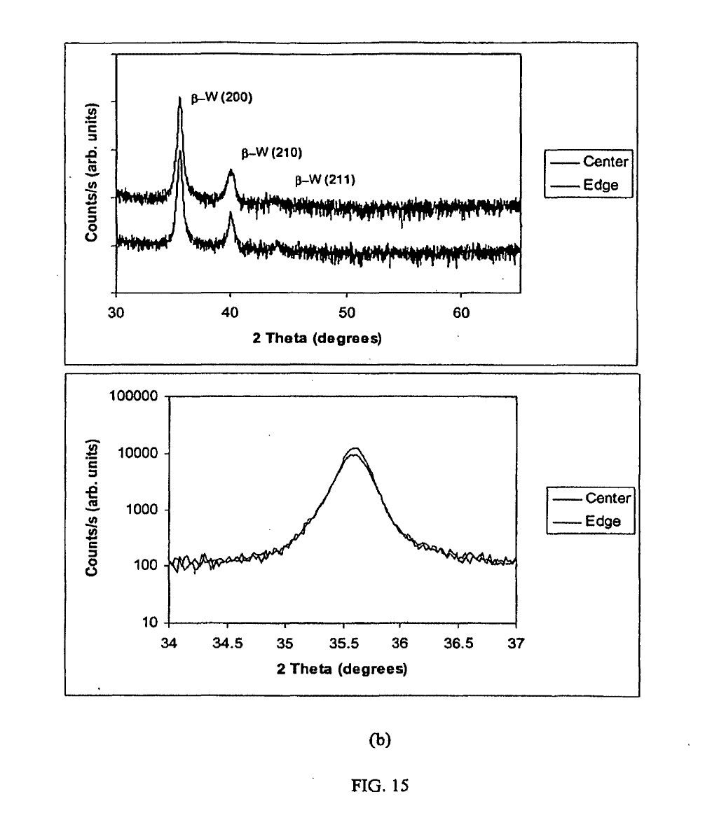

A resistivity measurement and an XRD scan were carried out as a standard characterization. In this study, the W film deposited at the center of the stage also showed a similar XRD result (FIG. 13) and film resistivity. Contrary to the current results, the film deposited at the edge shows β phase and a lower sheet resistance (not as low as the later samples, but about half of the sheet resistance for the film deposited at the center of the stage). In the earlier study, the sample deposited at the edge was actually closer to the center of the stage. The XRD result is shown in FIG. 15. Clearly, the crystal structure and resistivity of the W film are dependent on the location of the sample in the chamber. The formation of b.c.c. α-W and low resistivity are favored toward the edge of the perimeter of the sputtering stage. No stress measurement was conducted on those samples deposited in the earlier study.

### Example 2

### W Deposited on Cr Interlayer

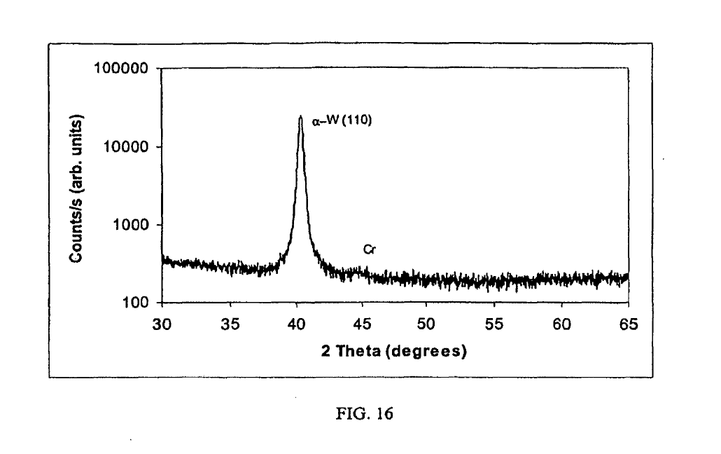

In this example, the deposition conditions for the W layer remained essentially the same, but a thin chromium layer was sputtered as an underlayer between the substrate and the W film with a 1-minute presputtering step. The chromium interlayer was deposited at an Ar flow rate of 30 sccm (Ar pressure around 4.5 mTorr) and at a 250 watt DC power level for 30 seconds. The thickness of the chromium layer was around 150 Å. The X-ray diffraction scan result is shown in FIG. 16, with highlighted details in Table 7.

The X-ray diffraction of the W/Cr film on a quartz substrate shows that there is a peak at 2θ˜40.35 degrees. This peak was later identified as the (110) peak of b.c.c. α-W. No peak around 35 degrees was observed, which corresponds to the (200) plane of A-15 β-W. The additional peak at 2θ around 44 degrees belongs to the (200) plane of the Cr interlayer. The XRD result indicates that the main crystal structure of this W film is the b.c.c. structure. As discussed above, W films deposited without the additional Cr interlayer have A-15 structure. Under a high oxygen concentration in the sputtering chamber without a long presputtering time (30 to 60 minutes as in the prior art) to remove the oxygen, a thin layer of Cr as an interlayer was simply introduced to obtain α phase W. As a result, these W films are α phase and not β phase which is of significant advantage. The X-ray diffraction results confirm that the crystal structure of all W films deposited on the Cr interlayer is b.c.c. α-W.

In addition, the XRD results also show that W films deposited under this condition have very strong (110) preferred orientation, i.e., (110) texture. This finding could be explained by the (110) plane of the b.c.c. structure being more stable due to its higher bond density along the (110) plane, resulting in a lowering of its surface energy. The sheet resistance of the W film measured, using four-point probe measurements, is 2.76Ω/□. After subtracting out the resistance of the Cr layer, the resistivity calculated from this sheet resistance measurement is 44.1 μ-cm.

TABLE 7
XRD results of W films deposited on glass and silicon
substrates with a Cr interlayer in between

| | W/Cr C | W/Cr/Si/C |
|---|---|---|
| Substrate | Quartz | Si |
| A-15 β-W | | |
| (200) plane (2θ = 35.67) | 0% | 0% |
| b.c.c. α-W | 100% | 100% |
| Strongest peak position (2θ) | 40.39 | 40.37 |
| Peak plane | (110)/b.c.c. α-W | (110)/b.c.c. α-W |
| FWH (B_{M}) (θ) | 0.3458 | 0.3411 |
| Lattice constant (Å) | 3.1555 | 3.157 |
| Grain size (Å) | 248 (±5) | 252 (±5) |

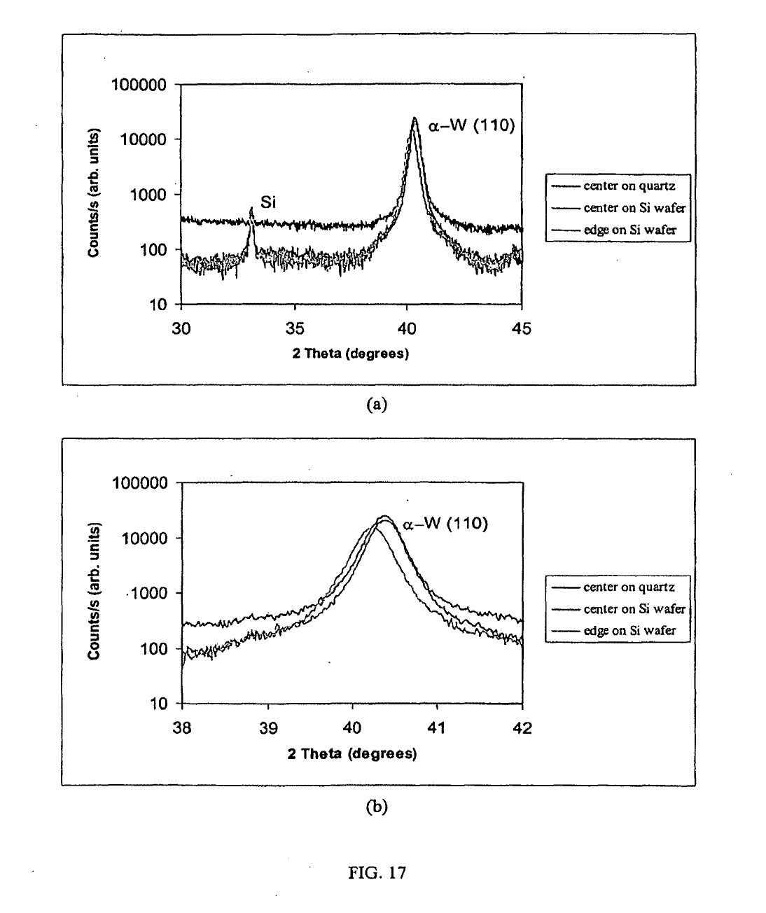

In addition to a quartz substrate, two Si wafers were also used as substrates for the stress measurement of the thin films. One Si wafer was placed at the center of the stage and the other wafer was placed at the edge of the stage. The XRD results of these two samples and the quartz sample deposited at the center are superimposed in FIG. 17 (a). An additional and more detailed graph around 40 degrees is shown in FIG. 17 (b). A summary of the XRD results and electrical properties of these films is shown in Table 8. The stress of the film was first measured by the balloon method. The stress data were then converted to the lattice constant using Eq. (8). The lattice constant obtained from Eq. (8) agrees with the lattice constant obtained from the XRD measurement. A significant stress difference was noted between the stress of the film deposited at the center and that deposited at the edge. Corresponding to this significant stress difference, W films with higher tensile stress also showed higher sheet resistance. With a deposition uniformity of 5% for films having a thickness around 1500 Å and with a 50 Å, resolution of the Dektek 3 surface profiler, the relative error of the sheet resistance (∈) is calculated by

∈=\sqrt{∈ₓ²+∈_{y}+ . . . ,}

where x, and y are independent error factors and ∈ₓ, and ∈_{y}, are relative error for each independent error factors. In this case, the two error factors are the uniformity of the Denton Discovery 18 Deposition System (5%) and the measurement error from the Dektek 3 (50 Å/1500 Å). The relative error for stress measurement is ±6%, which is much less than the sheet resistance difference measured between the two films. It is suspected that the difference in resistivity in this case may be due to a more positive stress at the edge, thus leading to a more compact microstructure with less oxygen or argon incorporation in the lattice.

Contrary to the negligible stress to compressive stress, in general for b.c.c. α-W films reported, the b.c.c. α-W of the W/Cr film shows a strong tensile stress (1.47 GPa at the center and 0.38 GPa at the edge). This result suggests that small tensile stress or compressive stress is not necessarily the natural condition for b.c.c. α-W films. Although the stress in the b.c.c. α-W was much larger than those reported for b.c.c. α-W films, the tensile stress in the A-15 β-W films was always larger than the b.c.c. α-W films deposited at the same position. With a Cr interlayer as an assistant, high tensile stress b.c.c. α-W films could be obtained under normal sputtering conditions. Without a Cr interlayer, the W films generally are tensile stress A-15 β-W.

TABLE 8
Summary of film properties from the W/Cr film deposited
at the center and at the edge of the stage

| | W/Cr/Si C | W/Cr/Si E |
|---|---|---|
| Sample position | Center | Edge |
| Sheet resistance (Ω/□) * | 2.66 | 1.55 |
| Film thickness (Å) | 1427 | 1504 |
| Resistivity (μΩ-cm) | 38 | 23 |
| Phase of film | α | α |
| (110) peak position (2θ) | 40.37 | 40.27 |
| Lattice constant (Å) | 3.1570 | 3.1645 |
| Stress (GPa) | 1.47 (T) | 0.38 (T) |
| Lattice constant (Å) | 3.1567 | 3.1627 |
| calculated by stress ** | | |

* Sheet resistance measured by four-point probe measurement.
** This is the lattice constant calculated from Eq. (8) with stress data obtained from the balloon method.

### Example 3

### Effects of Annealing on W Films

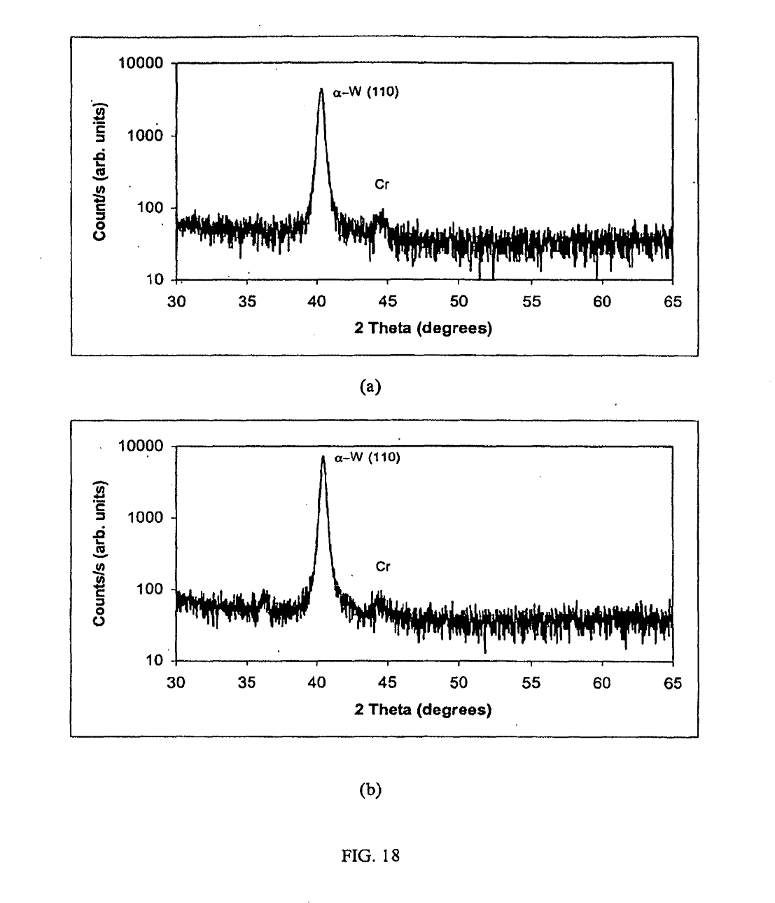

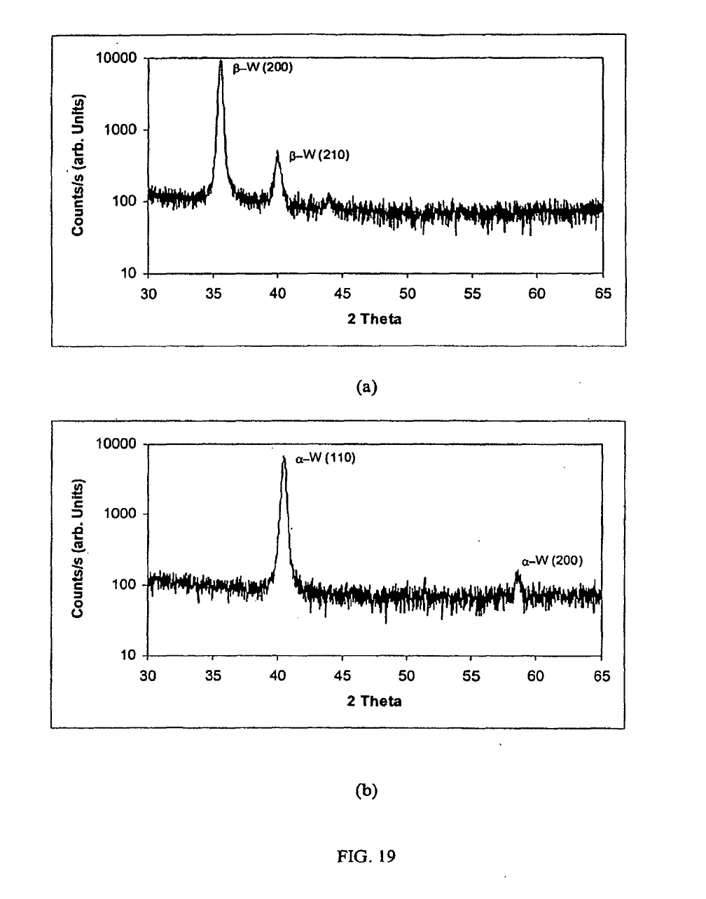

An annealing experiment was carried out to confirm that A-15 β-W is a metastable phase of W which can transform to the stable state W (b.c.c. α-W). The samples used for the annealing experiment were deposited on quartz substrates. Quartz was chosen as the substrate because it can withstand high temperatures without any degradation or outgassing which can contaminate the W film: Pure W was deposited on one side of the quartz slide and the Cr/W/Cr structure was deposited on the other side of the slide. The second chromium layer was initially used to prevent W oxidation but was later found to be unnecessary. Using the resistive heating method, the quartz slide was then annealed at 600° C. for 5 minutes under vacuum. The as-deposited and annealed W films were characterized by X-ray diffraction and four-point probe measurements. FIG. 18 shows the XRD pattern of an as-deposited W film with Cr interlayer and of the same film after annealing, respectively. FIG. 19 shows the XRD pattern of an as-deposited pure W film and of the same film after annealing. Table 9 shows a comparison and summary of the analyzed data obtained from X-ray diffraction of the films, respectively.

The as-deposited Cr/W/Cr structure has a b.c.c. α-W structure with a (110) preferred orientation. After the 600° C. annealing process, the microstructure of the Cr/W/Cr film remained b.c.c. α-W with the same (110) preferred orientation. A small increase of grain size was observed, which can be explained by grain coarsening during the annealing process. The resistivity of the Cr/W/Cr film after annealing was much lower (17 μΩ-cm) compared to the resistivity before annealing (44.1 μΩ-cm). This result may also be due to the grain coarsening effect and the increased amount of oxygen impurities diffusing away, which are generally observed during the annealing process. This phenomenon is not only specific to W films and has been observed for metal and ceramic material under annealing processes. On the other hand, the XRD results of the pure W film show that the β phase W completely transformed to the stable α phase W after annealing at 600° C. for 5 minutes. The new α phase W had an average grain size of 294 Å, which was smaller than the original β phase grain size (355 Å) and had a (110) preferred orientation, i.e., (110) texture. Comparing the grain size of the b.c.c. α-W obtained from annealing the A-15 β-W phase to those of the b.c.c. α-W obtained from the Cr/W/Cr film, the grain size obtained from the phase transformation was much larger than that obtained from the Cr/W/Cr film. In addition to the dominant (110) peak, a second significant peak, (200) α-W, was also observed at 2θ=58.526. This result suggests that the (200) and (210) grains of A-15 β-W with short-range atomic movement may directly transform to the (110) and the (200) grains of b.c.c. α-W (110), respectively. The resistivity of the pure W film after annealing dramatically decreased from 165 to 24 μΩ-cm, which agreed with the phase change from high resistivity β-W to low resistivity α-W as seen in the XRD data. The results confirmed that the β phase W was not a stable phase, and that the β phase W transformed irreversibly to the α phase after, for example, annealing at 600° C. for 5 minutes. This phase transformation and resistivity decrease of the A-15 β-W film were in agreement with the general observation in the prior art. Overall, the reported transformation temperatures ranged from the high 500 to 800° C. depending on the microstructure of the film.

TABLE 9
X-ray diffraction (XRD) results of the
W film before and after annealing.

| | | W—C | | WCr |
|---|---|---|---|---|
| | W—C | after | WCr | after |
| | as-deposited | annealing | as-deposited | annealing |
| A-15 β-w | 100% | 0% | 0% | 0% |
| (200) intensity | | | | |
| b.c.c. α-W | 0% | 100% | 100% | 100% |
| (110) intensity | | | | |
| Other | A-15 β-W | b.c.c. α-W | No | No |
| secondary peak | (210) | (200) | | |
| Grain size (Å) | 355 | 294 | 213 | 253 |
| Resistivity | 165 | 24 | 44.1 | 17 |
| (μΩ-cm) | | | | |

The crystal structure and the resistivity of the A-15 β-W films deposited under any given conditions remained the same after storage at room temperature for 2 years.

### Example 4

### Effects of the Base Pressure

It has been suggested that oxygen impurities in sputtering chambers may play an important role in the microstructure of pure W films. O'keefe et al., Shen et al. and other researchers indicated that impurities in sputtering chambers tend to stabilize A-15 β-W. The inventors have discovered that a phase change phenomenon has indicated that the effect of an additional Cr interlayer is much stronger than the oxygen impurity effect under normal deposition conditions, which suggests that the growth competition strongly favors the b.c.c. α-W when an additional Cr interlayer is sputtered first before sputtering the W layer as provided in the present invention. The limit of the effect of the additional Cr layer changing the crystal structure of the W thin films from the β to the α phase is evaluated by increasing the base pressure. The limit of the effect of an additional Cr interlayer will lie at the onset of the W changing back from the α to the β phase; that is, the oxygen impurity stabilized A-15 β-W phase is dominant. Therefore, a set of experiments was designed to evaluate the effect of oxygen impurities on W films deposited with and without a Cr interlayer. In this set of experiments, most of the sputtering conditions remained the same: (1) Ar flow rate 30 sccm, (2) Ar pressure around 4.5 mTorr, (3) 250 watts DC sputtering power for Cr and 200 watts DC sputtering power for W, and (4) 1-minute presputtering before deposition of each layer. The control factor in this experimental setting was the base pressure to which the sputtering chamber was pumped down to before introducing the Ar gas. Selected base pressures in the experiments were ˜1.0×10⁻⁶, ˜5.0×10⁻⁶, ˜1.0×10⁻⁵, 2.5×10⁻⁵, ˜3.5×10⁻⁵, and ˜5.0×10⁻⁵ Torr.

### Pure W Films

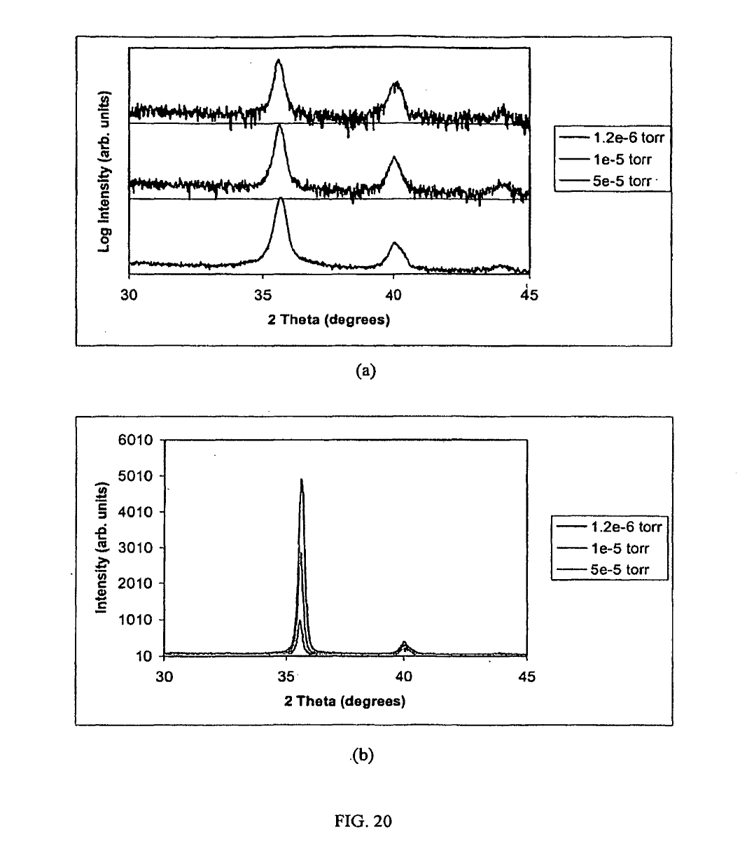

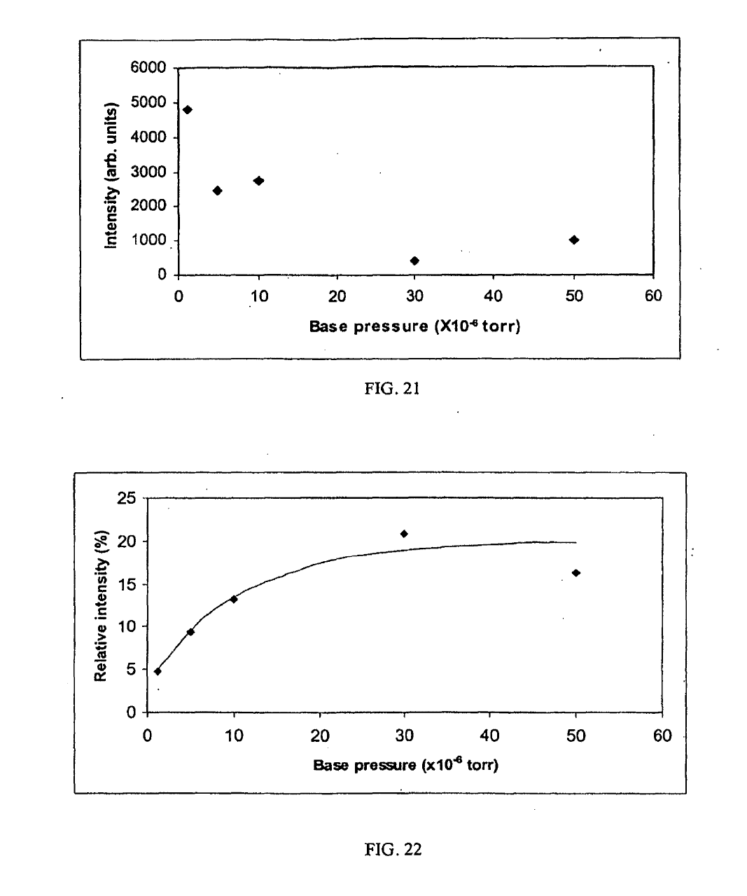

The XRD results of three films deposited on glass microslide substrates under different selected base pressures are shown in FIG. 20. In addition to the XRD patterns, the film characteristics and electrical properties are summarized in Table 10. All three films are β phase W with predominate (200) grains and a small amount of (210) grains. It was noticed that the intensity of the β-W (200) peak decreased as the base pressure increased (see FIG. 20 and FIG. 21). FIG. 21 suggests that there is a possible saturation for the intensity of the β-W (200) peak at higher base pressures. FIG. 22 was plotted with the relative intensity of the β-W (210) peak versus base pressure.

TABLE 10
X-ray results of W films on glass substrates at different base pressures.

| | 1 | 2 | 3 | 4 | 5 |
|---|---|---|---|---|---|
| Base pressure (Torr) | 1.2 × 10⁻⁶ | 5.0 × 10⁻⁶ | 1.0 × 10⁻⁵ | 3.0 × 10⁻⁵ | 5.0 × 10⁻⁵ |
| β-phase (200) peak | 35.67 | 35.63 | 35.62 | 35.66 | 35.58 |
| position (2θ) | | | | | |
| FWHM (degrees) | 0.2844 | 0.2438 | 0.2494 | 0.3085 | 0.2495 |
| β-phase (200) peak relative | 100 | 100 | 100 | 100 | 100 |
| intensity | | | | | |
| β-phase (210) peak relative | 4.80 | 9.34 | 13.16 | 20.82 | 16.32 |
| intensity | | | | | |
| β-W grain Size (Å) | 300 (±17) | 352 (±17) | 344 (±17) | 275 (±17) | 344(±17) |
| from (200) peak | | | | | |
| Film resistivity | 127 | 143 | 152 | 194 | 187 |
| (μΩ-cm) | | | | | |

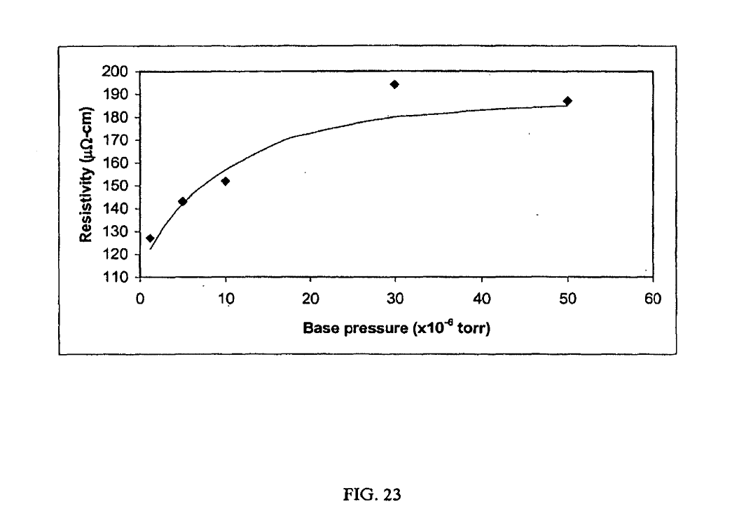

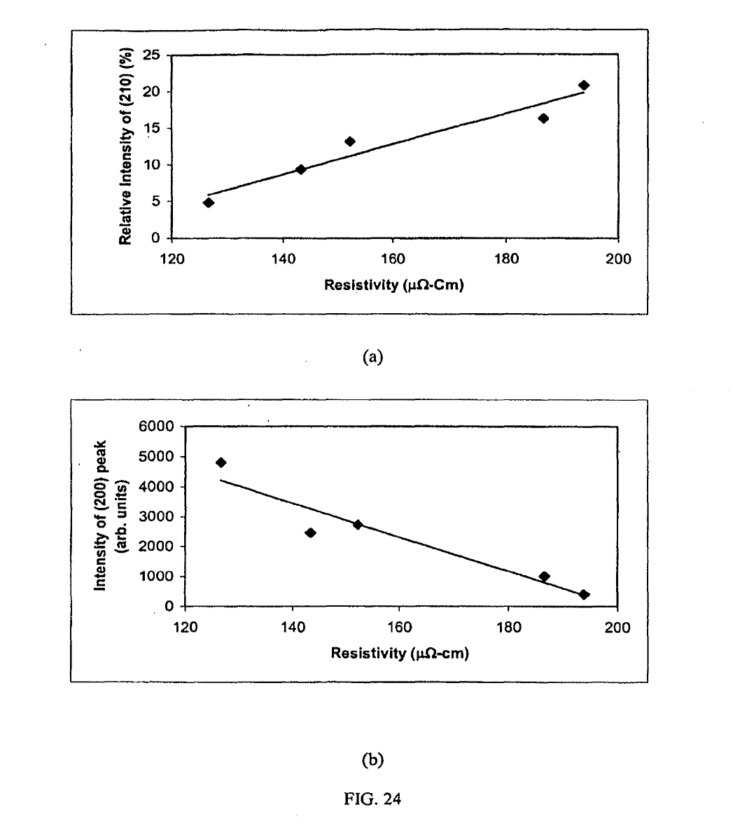

It is clear from FIG. 22 that there is a correlation between the base pressure and the relative intensity of the β-W (210) peak. Four-point probe measurements were performed on all films deposited under different base pressures. FIG. 23 is the resistivity of the W film versus the base pressure. There is a close correlation within FIG. 21, FIG. 22 and FIG. 23. All plots show a decrease or a monotonic increase at lower base pressure and a saturation at higher base pressures. Two plots were generated, with the film resistivity as the x axis, and the intensity of the β-W (200) peak (see FIG. 24 (a)) as they axis, or the relative intensity of β-W (210) peak (see FIG. 24 (b)). The plots suggest a linear correlation between the film resistivity and the intensity of β-W (200) (see FIG. 24 (a)). In addition, a linear correlation between the film resistivity and the relative intensity of the β-W (210) peak also exists in FIG. 24 (b). The exact relationship between the resistivity and the intensity of the β-W (210) peak is not clear. It is possible that the resistivity of β-W (210) is higher than β-W (200). Therefore, with a larger amount of β-W (210) grains in W film, the film resistivity is higher. On the other hand, the possibility that more impurities are incorporated into the β-W structure (higher oxygen content), which may also directly cause higher resistivity, cannot be excluded.

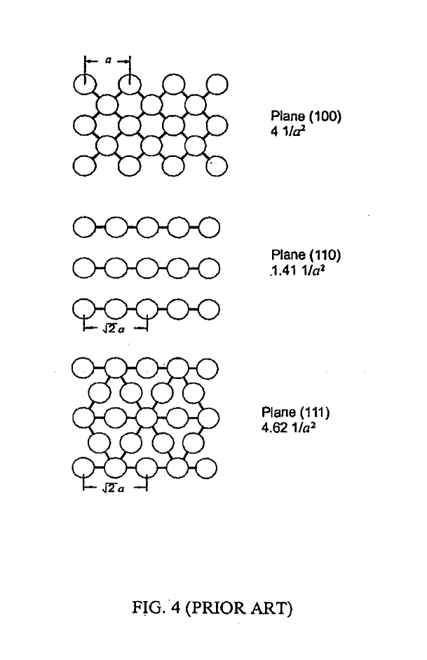

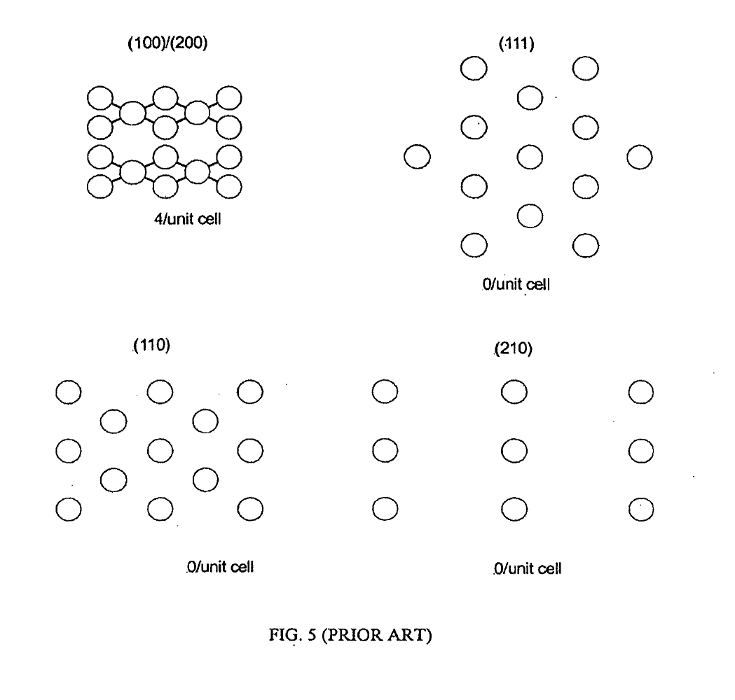

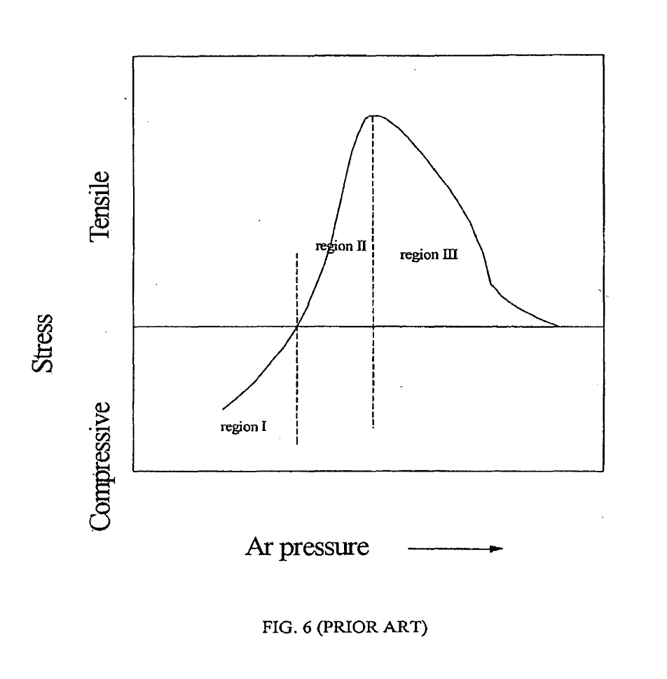

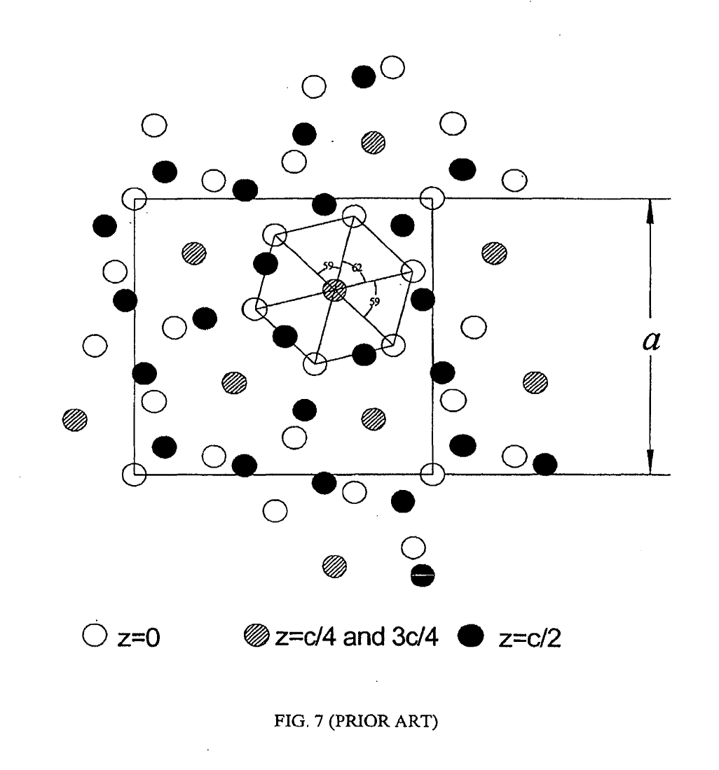

Comparing the XRD results of all films deposited at different base pressures (see FIG. 4.11), there is a decrease of intensity of the strongest peak, due to the (200) plane of β-W, as the base pressure increases. More importantly, although there is a relationship between the base pressure and the resistivity, the connection between the intensity of the β-W (200) peak and the resistivity of the films could not be ignored. The change in the intensity of the β-W (200) peak may be caused by the change of the preferred orientation to other peaks that cannot be detected by XRD, which is unlikely, or a change to β-W (210). Without being bound by any particular theory, another explanation could be the amorphous transformation or amorphorzation of W or W oxide. The oxygen impurities from the environment (chamber) may incorporate into amorphous W or amorphous W oxide in order to absorb the excess oxygen impurities. Amorphous W or amorphous W oxide has a higher resistivity than pure W. If the high resistivity of the film is contributed to by amorphous W or amorphous tungsten oxide rather than the β-W (210) plane grains, the (200) peak intensity of β-W in the film should decrease as the film resistivity increases. This explanation is in good agreement with the experimental results.

### W/Cr Film

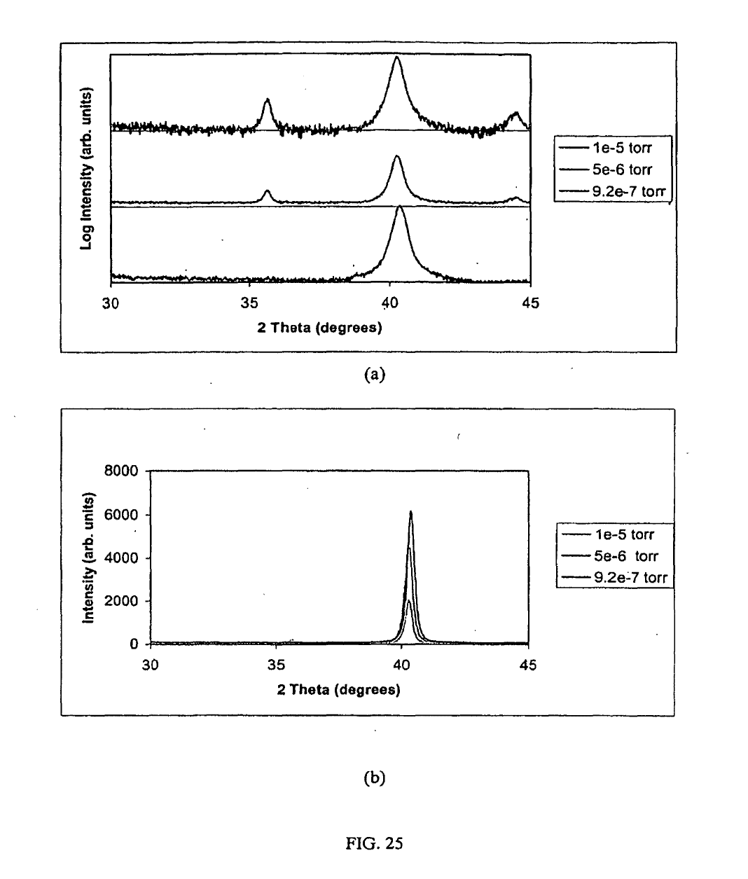

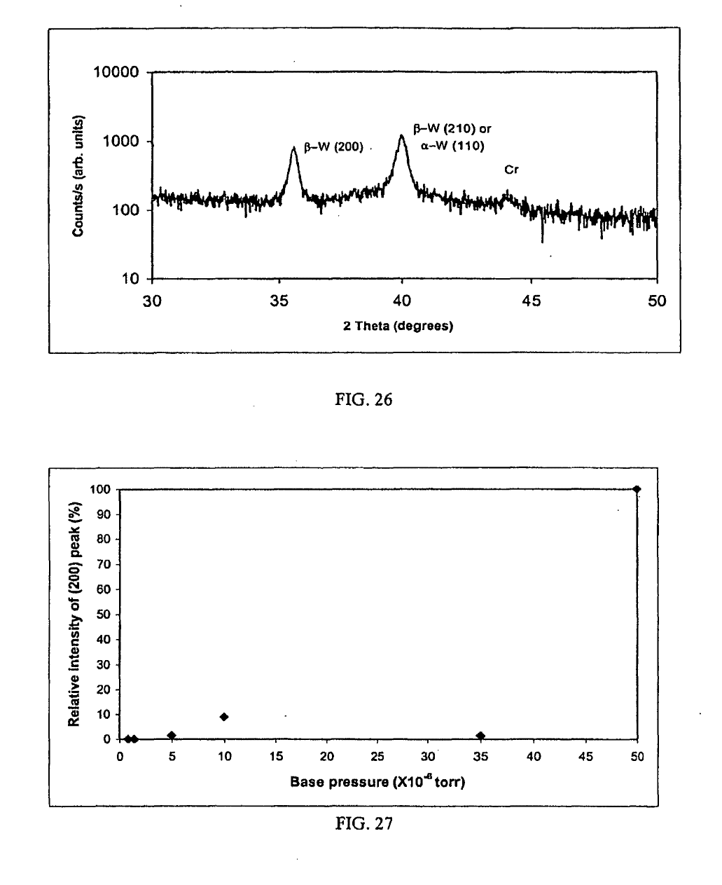

The XRD patterns of W/Cr films deposited with base pressures of 9.2×10⁻⁷, 5.0×10⁻⁶, and 1.0×10⁻⁵ Torr, respectively, are shown in FIG. 25. In addition to the XRD patterns, the film characteristics and electrical properties are summarized in Table 11. First, the XRD scans of sample 1 to sample 4 are very similar. The last sample (sample 5) was different from the rest. The XRD results of the W/Cr film deposited with a base pressure of 5×10⁻⁵ Torr (sample 5) is shown in FIG. 26. The first peak is located at 35.63 degrees, which is identified as β-W (200) (see Table 2). The second peak is located at 40.01 degrees, which may belong to β-W (210) or α-W (110) (see Table 1 and Table 2). The lattice constant calculated from this 2θ value for β-W (210) and α-W (110) are 5.035 Å and 3.184 Å, respectively. The lattice constant obtained from the β-W (200) peak is 5.035 Å. This value is the same as the lattice constant calculated under the assumption that the β-W (210) is at 40.01 degrees. In general, the amount of β-W present in the W/Cr film increases as the base pressure increases as shown in FIG. 26. This finding indicates that the oxygen in the chamber still contributes to the amount of β phase present in the films. The XRD result from sample 5 suggests that, although the α phase becomes more stable due to the additional Cr interlayer, the β phase still can become a more metastable phase as the concentration of oxygen impurities exceeds a certain base pressure.

TABLE 11
X-ray results of the W/Cr/substrate film system at different base pressures

| | 1 | 2 | 3 | 4 | 5 |
|---|---|---|---|---|---|
| Base pressure (Torr) | 9.2 × 10⁻⁷ | 5.0 × 10⁻⁶ | 1.0 × 10⁻⁵ | 3.5 × 10⁻⁵ | 5.0 × 10⁻⁵ |
| α-phase (110) peak | 40.37 | 40.28 | 40.27 | 40.23 | 40.01* |
| position (2θ) | | | | | |
| FWHM (degrees) | 0.3411 | 0.359 | 0.337 | 0.2955 | 0.423 |
| α-phase (110) peak relative | 100 | 100 | 100 | 100 | NA* |
| intensity | | | | | |
| β-phase (200) peak | NA | 35.61 | 35.60 | 35.63 | 35.63 |
| position (2θ) | | | | | |
| β-phase (200) peak relative | 0 | 1.46 | 8.97 | 1.34 | 100 |
| intensity | | | | | |
| β-W grain size (Å) | NA | NA | 335 (±17^{†}) | NA | 258 (±17^{†}) |
| from (200) peak | | | | | |
| α-W grain size (Å) | 251.8 (±5^{†}) | 239 (±7^{†}) | 255 (±7^{†}) | 292 (±7^{†}) | NA |
| from (110) peak | | | | | |
| Film resistivity | 38 | 69 | 90 | 67 | 232 |
| (μΩ-cm) | | | | | |

*Peak identified as β-phase (210) peak instead of α-phase (110) peak.
^{†}The error is calculated based on the step size of 2θ = 0.02 degrees at the peak in the XRD scan.

In this experiment, it is also noticed that the base pressure of the sputter condition at which a considerable amount of β-W could be present in the W films was significantly higher compared to the base pressure reported in the prior art. All of the above suggest that the chromium-assist technology reduces the influence of the base pressure and oxygen impurities present in the sputtering chamber. The upper limit of the base pressure required for sputter-deposited α-W films could be dramatically increased by using this chromium-assist technology. In addition, the quality of a vacuum system would not be as critical.

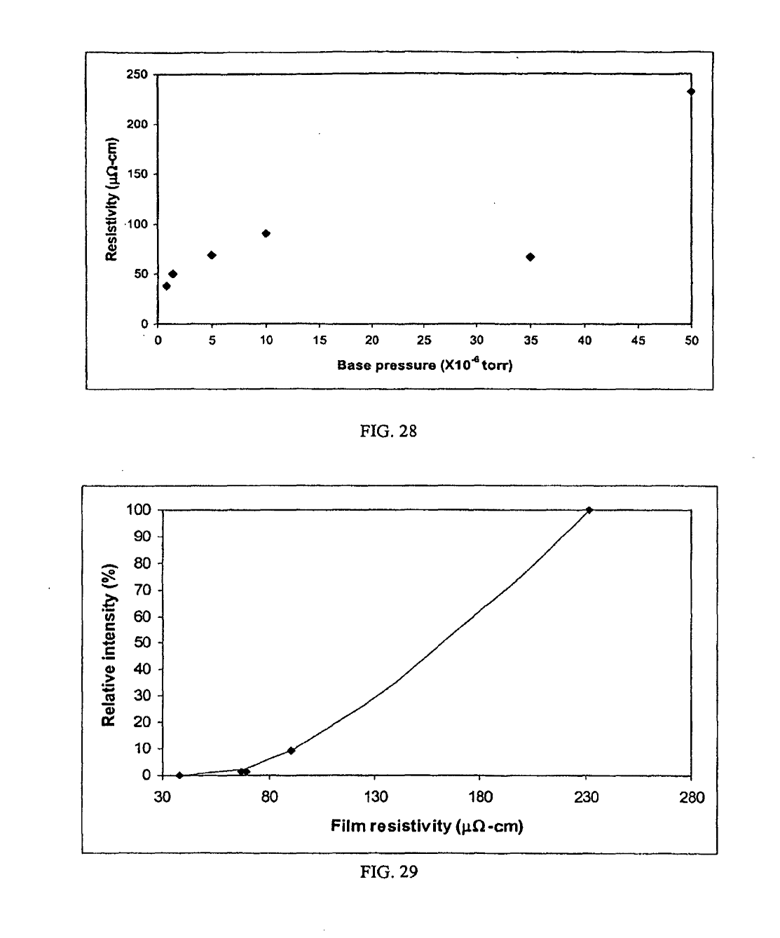

The resistivities calculated from the sheet resistance of the films at different base pressures are shown in FIG. 28. There is an indication that the resistivity of a film increases slowly as the base pressure increases. With the high oxygen impurities associated with higher base pressures, these oxygen impurities will either interstitially or substitutionally incorporate in the α-W films. Other excess oxygen will incorporate along the grain boundary. The excess oxygen will increase the film resistivity. As base pressure reaches a certain level, A-15 β-W is formed (sample 5). At this moment, the resistivity of this film is 232 μΩ-cm compared to 38 μΩ-cm for b.c.c. A-15. The relationship between the resistivity and the amount of β-W is shown in FIG. 29. Unlike the linear relationship for the β-W films, it seems that the amount of β-W increases significantly as the resistivity increases regardless of the base pressure for the W/Cr films (the abnormal data point in FIG. 27 follows the trend tendency of the data in FIG. 29). The high resistivity of the sputtered layer is simply due to the high resistivity of the β-W.

In summary, the chromium-assist technology according to one embodiment of the present invention aided in obtaining an α phase sputter-deposited W film up to a base pressure of approximately 3.5×10⁻⁵ Torr for standard-sputtering conditions. At base pressures in the range of 5.0×10⁻⁵ Torr, oxygen impurities become a dominant factor, and as a result, β-W becomes the dominant phase in the films deposited under this condition.

### Example 5

### Effects of Interlayer Metals

Au, Cu, Al, Cr, Pt, and Ni were selected as interlayer metals, since they are among the most common sputter-deposited materials and are readily available. All interlayer metals were deposited at the same Ar pressure as the deposited W with one-minute presputtering time to remove any contamination on the target. The thickness of the interlayer is controlled by adjusting the sputtering time. The thickness is around 200-300 Å to cover the substrate area entirely. Another set of samples was deposited with only interlayer metals, after which X-ray diffraction measurements were performed to identify the crystal structure of the interlayer metals. Table 12 shows a summary of the XRD results of all interlayer metals.

The XRD results of W films deposited on various interlayer metals are summarized in Table 13. Additional runs of samples with each structure were fabricated in an effort to eliminate any single event being viewed as the norm for that particular metal. In addition, the XRD results of W deposited on a (100) Si wafer and W deposited on a quartz substrate were added to Table 13 for comparison. It should be noted that the β/α phase ratio in the Ni, Cu, and Al systems is strongly dependent on the position of the sample in the sputtering chamber. All films listed in Table 12 are those deposited at the center of the stage.

TABLE 12
Summary of the XRD results of metal films used as an interlayer for
W films deposited on glass microslides

| | Au | Pt | Ni | Cu | A1 | Cr | Ta |
|---|---|---|---|---|---|---|---|
| 1st peak (2θ) | 38.21 | 39.76 | 44.37 | 43.44 | 38.58 | 44.40 | 33.88 |
| Plane of 1st peak | (111) | (111) | (111) | (111) | (111) | (110) | (200) |
| 2nd peak (2θ) | 44.39 | — | — | — | 44.79 | — | 38.37 |
| Plane of 2nd peak | (311) | — | — | — | (200) | — | (110) |
| Crystal structure | f.c.c. | f.c.c. | f.c.c. | f.c.c. | f.c.c. | b.c.c. | β-Ta (200) or A- |
| | | | | | | | 15 mix with |
| | | | | | | | b.c.c. (110) |
| Peak used to calculate | (111) | (111) | (111) | (111) | (111) | (110) | (200) and (110) |
| lattice constant | | | | | | | |
| Lattice constant (Å) | 4.077 | 3.923 | 3.533 | 3.605 | 4.039 | 2.883 | 4.661 and 3.315 |
| Preferred orientation | (111) | (111) | (111) | (111) | (111) | (110) | NA |

TABLE 13
X-ray diffraction (XRD) results of W films deposited on different interlayers

| | W on quartz | AuW | PtW | NiW | CuW | A1W | W/Cr (C) | W on Si |
|---|---|---|---|---|---|---|---|---|
| Interlayer or substrate | quartz | Au | Pt | Ni | Cu | A1 | Cr | Si |
| Relative intensity of A-15 (200) | 100 | — | — | 100 | 31.60 | 18.56 | — | 100 |
| (%) | | | | | | | | |
| A-15 (200) 2θ | 35.576 | — | — | 35.632 | 35.572 | 35.583 | — | 35.598 |
| Relative intensity of α-W (110) | — | 100 | 100 | 63.43 | 100 | 100 | 100 | — |
| (%) | | | | | | | | |
| α-W (110) 2θ | — | 40.29 | 40.35 | 40.35 | 40.29 | 40.37 | 40.39 | — |
| The percentage of α-W in the | 0 | 100 | 100 | NA | NA | NA | 100 | 0 |
| film* | | | | | | | | |
| Lattice constant of A-15 (Å) | 5.043 | — | — | 5.035 | 5.043 | 5.042 | — | 5.040 |
| Lattice constant of α-W (Å) | — | 3.1632 | 3.1585 | 3.1583 | 3.1634 | 3.1571 | 3.1555 | — |
| Grain size (Å)/dominant phase | 355/β | 226/α | 261/α | 354/β | 236/α | 291/α | 248/α | 319/β |

*The percentage of α-W in the film for NiW, CuW, and CuW was calculated by a different method and presented in Table 4.10.

The XRD results show three types of W films. W deposited on the Si substrates and W deposited on the glass substrates show only A-15 β-W. W deposited on an interlayer metal surface such as Au, Pt, and Cr exhibit the b.c.c. α-W structure. No trace of A-15 β-W was observed in these films. W films deposited on interlayer surfaces such as Ni, Cu, and Al showed a mixture of the A-15 β-W and the b.c.c. α-W. The amount of the b.c.c. α-W was W/Ni>W/Cu>W/Al.

A direct comparison method was conducted to analyze the XRD results for quantitatively estimating the concentration of each phase. This method could be used to quantitatively determine the concentration of different phases in the polycrystalline aggregate. This method was developed by Acerbach and Cohen. Assume that the material has only two phases. The diffracted intensity is then given by:

$$I = \frac{{K}_{2} R}{2 μ} \qquad ( 10 )$$

where K₂ is a constant, dependent on the type and amount of the diffracting substance. The details of the constant K₂ are described by the following equation:

$${K}_{2} = ( \frac{{I}_{0} A {λ}^{3}}{32 π r} ) [ ( \frac{{μ}_{0}}{4 π} ) \frac{{e}^{4}}{m} ] \qquad ( 11 )$$

where I₀=intensity of the incident beam (joules sec⁻¹ m⁻²), A=cross-sectional area of incident beam (m⁻²), λ=wavelength of the incident beam (m), r=radius of the diffractometer circle (m), μ₀=4π×10⁻⁷ (m kg C⁻²), e=charge of the electron (C), and m=mass of the electron (kg). The R in Eq. (10) is dependent on θ, hkl, and the type of substance. The details of R are given by:

$$R = ( \frac{1}{{υ}^{2}} ) [ {\vert F \vert}^{2} p ( \frac{1 + {cos}^{2} 2 θ}{{sin}^{2} θ cos θ} ) ] ( {e}^{- 2 M} ) \qquad ( 12 )$$

where ν is the volume of unit cell (m³); the remaining variables are defined in Section 2.2, Eq. (1). For the same composition with different phases, the values of K₂ and μ are the same for both phases. The ratio of the diffracted intensity in each phase is:

$$\frac{{I}_{α}}{{I}_{β}} = \frac{{R}_{α} {C}_{α}}{{R}_{β} {C}_{β}} \qquad ( 13 )$$

where C is the concentration. The ratio of R_{α}/R_{β} for the (110) peak of α-W to the (200) peak of β-W is 0.17. Therefore, the ratio of C_{α}/C_{β} could be rewritten as:

$$\frac{{C}_{α}}{{C}_{β}} = 0.17 \frac{{I}_{α}}{{I}_{β}} \qquad ( 14 )$$

It should be noted that this method was developed for polycrystalline aggregates. Eq. (12) is used for powder samples, with random orientation in the sample. Assume that the films have 100% preferred orientation, which means that all grains have the (110) plane perpendicular to the film surface for the b.c.c. α-W and have the (002) plane perpendicular to the film surface for the A-15 β-W. Therefore, the p in Eq. (12) must be removed because the probability for the (110) grains (b.c.c. α-W) or the (002) grains (A-15 β-W) is one. Eq. (14) could then be rewritten as:

$$\frac{{C}_{α}}{{C}_{β}} = 0.35 \frac{{I}_{α}}{{I}_{β}} \qquad ( 15 )$$

Due to the preferred orientation in the W films, the probabilities for grains with different orientations are not equal. In the A-15 β-W films, a very weak (210) peak was observed. However, in the b.c.c. α-W films, only one peak was observed at low angle. Therefore, it could be assumed that the degree of orientation for both phases is also different. It is believed that the true concentration of each phase lies between these two values and towards the value obtained from Eq. (15). Table 14 presents the raw XRD data, the data obtained from Eq. (14), and the data obtained from Eq. (15).

In conclusion, the material on which W is deposited has a major effect on whether A-15 β-W or b.c.c. α-W dominates in sputtered W thin films.

TABLE 14
Summary of the α-W concentration obtained from different XRD analysis methods

| Sample | W | AuW | PtW | NiW | CuW | A1W | W/Cr (C) | W on Si |
|---|---|---|---|---|---|---|---|---|
| Relative intensity of A-15 (200) (%) | 100 | 0 | 0 | 100 | 31.60 | 18.56 | 0 | 100 |
| Relative intensity of α-W (110) (%) | 0 | 100 | 100 | 63.43 | 100 | 100 | 100 | 0 |
| α-W concentration from raw XRD data | 0 | 100 | 100 | 38.8 | 76.0 | 84.3 | 100 | 0 |
| (%) | | | | | | | | |
| α-W concentration from Eq. (4.5) (%) | 0 | 100 | 100 | 9.7 | 35.0 | 47.8 | 100 | 0 |
| α-W concentration from Eq. (4.6) (%) | 0 | 100 | 100 | 18.2 | 52.6 | 65.3 | 100 | 0 |

### Example 6

### Ta Deposited on Glass

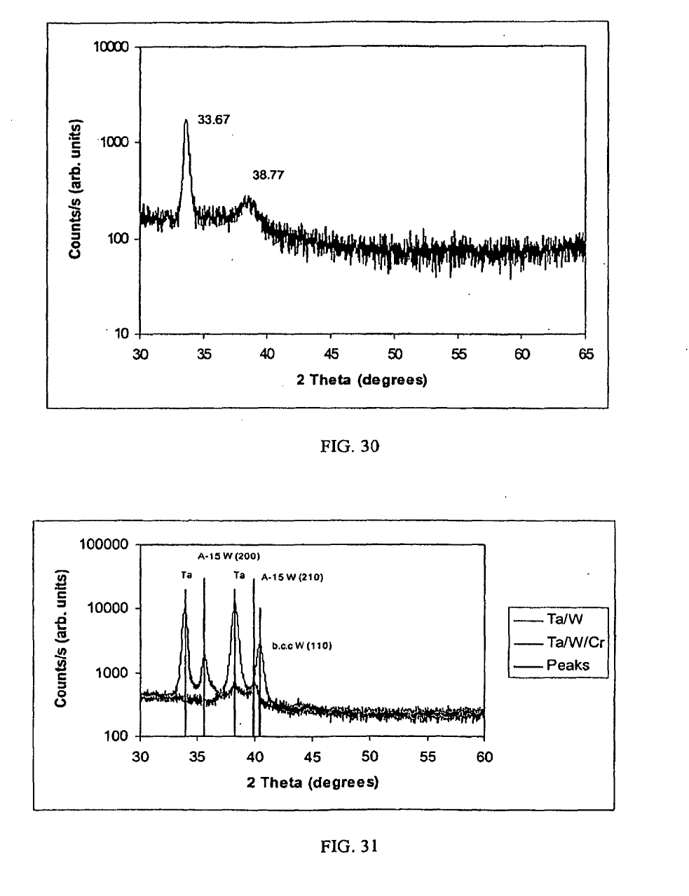

Ta films were deposited with sputter conditions of a 1-minute presputtering, a DC power of 200 Watts, a deposition time of 7 minutes, an Ar pressure of 4.6 mTorr, and a base pressure of 3×10⁻⁶ Torr. The Ta film samples were deposited on either glass microslides or on Si wafers. The films deposited on Si wafers were used to measure the film thickness and stress of the film. The measured film thickness and stress of the film were 1326 Å and 0.07 GPa, respectively. An XRD measurement was performed on the film deposited on glass. The films deposited within several runs under the same deposition conditions were consistent. FIG. 30 shows the XRD results of the Ta film deposited on glass, with peaks at 2θ=33.67 degrees and 2θ=38.77 degrees. Comparing the X-ray diffraction pattern to the JCPDS data of b.c.c. Ta where the first peak is around 2θ=38.47 degrees, the 2θ=38.77 degrees peak may be due to the (110) plane of b.c.c. Ta. This peak could also be due to the (202) plane of β-tetragonal Ta or the (210) plane of A-15 Ta. The 2θ=33.67 degrees peak could only be due to the (002) plane of β-tetragonal Ta or the (200) plane of A-15 Ta. With a relatively high intensity for the peak around 2θ=33.67 degrees, it is clear that the Ta film deposited on glass has a high degree of preferred orientation. Other techniques, such as TEM and STEM, could be used to further detect the prohibited planes in X-ray diffraction measurement. TEM could provide more information of the prohibited planes to further identify the crystal structure of the Ta film. It is believed that the crystal structure of the Ta films on glass is β-tetragonal Ta, and the very weak peak at 2θ=38.77 degrees may belong to the (202) plane of the β-tetragonal Ta.

### Example 7

### Ta/W and Ta/W/Cr Thin Films

Samples with Ta/W and Ta/W/Cr (W on Ta, Ta on Cr, and Cr on substrate) structures were deposited on glass and (100) Si wafer substrates. Samples deposited on the Si wafers were used to measure the film thickness and the stress of the film. The sputter conditions of an 1-minute presputtering on all sputter targets, a 4.6 mTorr Ar pressure, and a base pressure of 3×10⁻⁶ Torr were applied on both film structures. The DC sputter power was 200 Watts for Ta, 200 Watts for W, and 250 Watts for Cr (if applied). The deposition time was 7 minutes for Ta, 1 minute for W, and 30 seconds for Cr (if applied).

The additional Cr layer also changes the crystal structure of the W film on which Ta will be deposited. The W film with an additional Cr layer has a b.c.c. structure, as shown and discussed above. The W film without an additional Cr layer has an A-15 structure. The thickness and stress of the Ta/W film were 1598 Å and 0.96 GPa, respectively. The thickness and stress of the Ta/W/Cr film were 1870 Å and 0.71 GPa, respectively. X-ray diffraction measurements were performed on the samples of Ta/W/glass substrate and Ta/W/Cr/glass substrate. FIG. 30 shows the X-ray pattern of the Ta/W and Ta/W/Cr films superimposed on each other. The dark line is the XRD pattern of the Ta/W film and the gray line is the XRD pattern of the Ta/W/Cr film. In the XRD pattern of the Ta/W film, a b.c.c. α-W (110) peak was observed at 2θ=40.5 degrees, as indicated in FIG. 31. In addition to the W peaks, there is a peak at 2θ=38.3 degrees due to the Ta layer. This peak could be due to either the (110) plane of b.c.c. Ta, or the (202) plane of β-tetragonal Ta, or the (210) plane of A-15 Ta. Due to the large degree of preferred orientation in the metastable phase of Ta, as shown in FIG. 30, the crystal structure of the Ta layer in Ta/W/Cr is most likely to be a b.c.c. structure (see Table 15). On the other hand, there are two A-15 β-W peaks of the (200) and the (210) planes for 2θ around 35.6 and 40 degrees, respectively, in the XRD pattern of the Ta/W/Cr film. In addition to these W peaks, there are two peaks due to the Ta layer. One peak is at 2θ=33.88 degrees and the other is at 2θ=38.3 degrees. The dominant peak is the peak at 2θ=33.88 degrees. This peak, however, is not due to the b.c.c. Ta (see Table 15); it is most likely due to the metastable phase of Ta, the (002) peak of the β-tetragonal Ta, or the (200) peak of the A-15 Ta. It is difficult to distinguish the β-tetragonal Ta from the A-15 Ta with only two Ta peaks, both of which could be contributed to by both crystal structure types. Nevertheless, whether the crystal structure of Ta in the Ta/W film is β-tetragonal Ta or A-15 Ta, it is clear that the crystal structure of the Ta film can be modified by the crystal structure of the underlayer metal. Ta deposited on b.c.c. α-W has a b.c.c. crystal structure. Ta deposited on A-15 β-W has either a tetragonal or an A-15 crystal structure.

This example shows that Ta, like W, has a metastable phase, which is a preferred phase for base pressures around and above 3×10⁻⁶ Torr. This metastable phase changes to a stable b.c.c. phase when deposited on a b.c.c. W interlayer.

### Example 8

### Ta Film Deposited on Other Metal Films

Ta films were sputter-deposited on other deposited metal films (Cr, Cu, Al, and Au), as was done above for the W films. The substrates used in these experiments were glass microslides and (100) Si wafers. A balloon stress measurement method was performed on films deposited on Si wafers. It was noted that the film stress obtained by this method was an average value of the film in terms of depth and area. X-ray diffraction measurements were performed on films deposited on glass microslides. A summary of all Ta films is shown in Table 16.

From the XRD scans of the Ta/Cu and Ta/Al films, the peak at 2θ around 33.5 degrees is the strongest peak, with a very weak peak at 2θ around 38.0 degrees (less than 6% in relative intensity). This finding suggests that Ta films deposited on Cu or Al interlayers have the metastable Ta phase, either β-tetragonal Ta or A-15 Ta (see Table 15). These two films and the Ta on glass film all show a high degree of preferred orientation due to the absence of other planes in the XRD patterns. It was concluded that the metastable phase of Ta (i.e., β-tetragonal Ta or A-15 Ta), tends to show a high degree of preferred orientation, as with most sputter-deposited metal films. This preferred orientation would be either the (002) plane of β-tetragonal Ta or the (002) plane of A-15 Ta. The Ta metastable phase generally has a very high degree of preferred orientation towards the peak located at 2θ around 33.5 degrees.

TABLE 15
A list of the possible reflection planes and their respective
2θ and relative intensity values of powder samples
in the X-ray diffraction pattern for b.c.c. Ta, β-tetragonal
Ta, and A-15 Ta in the range of the 2θ = 30 to 60 degrees

| b.c.c. Ta* | | | β-tetragonal Ta** | | | A-15 Ta*** | | |
|---|---|---|---|---|---|---|---|---|
| hkl | 2θ | Int | hkl | 2θ | Int | hkl | 2θ | Int |
| 110⁺ | 38.184 | 100 | 221⁺ | 29.888 | 1 | 200 | 34.060 | 12 |
| 200⁺ | 44.392 | 52 | 311 | 32.387 | 8 | 210 | 38.227 | 100 |
| 211⁺ | 64.576 | 32 | 002⁺ | 33.692 | 40 | 211 | 42.040 | 75 |
| | | | 400⁺ | 34.784 | 1 | 222 | 60.964 | 7 |
| | | | 410 | 36.281 | 80 | | | |
| | | | 330 | 37.392 | 55 | | | |
| | | | 202⁺ | 38.200 | 55 | | | |
| | | | 212 | 39.240 | 80 | | | |
| | | | 411 | 40.208 | 100 | | | |
| | | | 331 | 41.186 | 65 | | | |
| | | | 312 | 44.050 | 18 | | | |
| | | | 510 | 45.186 | 1 | | | |
| | | | 322 | 46.814 | 4 | | | |
| | | | 431 | 47.621 | 5 | | | |
| | | | 511 | 48.512 | 6 | | | |
| | | | 402 | 49.439 | 1 | | | |
| | | | 521 | 51.099 | 1 | | | |
| | | | 432 | 56.781 | 4 | | | |
| | | | 611 | 57.557 | 5 | | | |
| | | | 313 | 59.387 | 1 | | | |
| | | | 621 | 59.853 | 12 | | | |
| | | | 541 | 60.545 | 1 | | | |

*a (lattice constant) = 3.301 Å, from the Joint Committee for Powder Diffraction Standards (JCPDS).
**a = 10.194 Å, c = 5.313 Å, from the JCPDS.
***a = 5.26 Å, calculated based on the same A-15 structure for W with W replaced with Ta atoms.
⁺Peaks normally observed in thin films.

TABLE 16
Summary of Ta films deposited on Cr, Cu, Al, and Au

| | Ta on Cr | Ta on Cu | Ta on A1 | Ta on Au | Ta on W | Ta on W/Cr |
|---|---|---|---|---|---|---|
| Film stress (GPa) | 0.22 | 0.50 | 0.29 | −0.43 | 0.96 | 0.71 |
| 1st peak** in XRD | 33.50 | 33.61 | 33.54 | 38.23 | 33.91 | 38.31 |
| (2θ) | | | | | | |
| Suggested crystal | β or A-15 | β or A-15 | β or A-15 | b.c.c. | β or A-15 | b.c.c. |
| structure* | | | | | | |
| Relative intensity | 38.68 | 100 | 100 | 100 | 100 | 100 |
| (%) | | | | | | |
| 2nd peak** in XRD | 38.04 | 38.18 | 38.28⁺ | — | 38.31 | — |
| (2θ) | | | | | | |
| Suggested crystal | b.c.c. or β | b.c.c. or β | b.c.c. or β | — | b.c.c. or β | — |
| structure | | | | | | |
| Relative intensity | 100 | 5.45 | 4.48 | — | — | — |
| (%) | | | | | | |
| Dominant phase⁺⁺ | b.c.c. | β | β | b.c.c. | β | b.c.c. |

*β = β-tetragonal crystal structure, b.c.c. = body center cubic crystal structure.
**Peak due to Ta layer in XRD scans.
⁺Peak overlap with (111) Al.
⁺⁺Assuming peak at 2θ≈33.5° belongs to β-tetragonal Ta and peak at 2θ = 38° belongs to b.c.c. Ta. Items in bold are the more likely structure.

In comparison of the results obtained in this example with the prior art, the as-deposited Ta/Cu multilayer film also had β-tetragonal Ta present. Unlike the β-tetragonal Ta in the Ta/Al film, their as-deposited Ta/Al multilayered film showed a b.c.c. crystal structure. An epitaxial relation of the Al and b.c.c. Ta was given to explain the phenomenon. A close match of less than 0.04% difference was found along the <−111> direction of the (110) plane of b.c.c. Ta and the <−111> direction of the (111) plane of f.c.c. Al. In the perpendicular direction, there was no matching. In general, a 2-D matching is necessary for epitaxial growth. With the same assumption, a 2-D matching was considered for any epitaxial relation between Ta and the interlayer metals. The simulation results appear to support the experimental results for Ta/Al.

The foregoing description of specific embodiments and examples of the invention have been presented for the purpose of illustration and description, and although the invention has been described and illustrated by certain of the preceding examples, it is not to be construed as being limited thereby. They are not intended to be exhaustive or to limit the invention to the precise forms disclosed, and many modifications, improvements and variations within the scope of the invention are possible in light of the above teaching. It is intended that the scope of the invention encompass the generic area as herein disclosed, and by the claims appended hereto and their equivalents.

1. A method of making a thin film on a substrate, the method comprising:
forming a first layer comprising a metal on a substrate; and
forming a second layer on the first layer under a base pressure in a range from about 1.0×10-7 Torr to about 3.5×10-5 Torr, the second layer comprising an alpha-phase structure formed of at least one of a refractory metal, a refractory metal alloy, a refractory metal compound and a refractory metal system.

2. The method of claim 1, wherein forming the first layer or forming the second layer comprises at least one of: sputtering, chemical vapor deposition, atomic vapor deposition, thermal evaporation and deposition, and electron beam evaporation.

3. The method of claim 1, wherein forming the second layer comprises sputtering.

4. The method of claim 1, further comprising annealing.

5. The method of claim 1, wherein the substrate comprises at least one of silicon, quartz, ceramic, glass, alumina, sapphire, or gallium arsenide.

6. The method of claim 1, wherein the first layer comprises chromium and the second layer comprises tungsten.

7. The method of claim 1, wherein the first layer assists in the formation of the alpha-phase second layer.

8. The method of claim 1, wherein the forming of the first layer comprises forming an assistant layer to assist in forming the alpha-phase second layer by reducing an influence of the base pressure and oxygen impurities around the second layer.

9. The method of claim 1, wherein the second layer is formed under a base pressure on an order of 1×10-6 Torr.

10. The method of claim 1, wherein the second layer is formed under a base pressure on an order of 1×10-5 Torr.
